(19) United States
(12) Patent Application Publication
(10) Pub. No.: US 2026/0293103 A1
(43) Pub. Date: Sep. 24, 2026

(54) SEMICONDUCTOR DEVICE

(71) Applicant: Kioxia Corporation, Tokyo (JP)

(72) Inventors: Taiki FUJIMOTO, Yokkaichi Mie (JP); Yuya MATSUZAWA, Moriya Ibaraki (JP); Naoki KAI, Kuwana Mie (JP); Toshifumi KURODA, Yokkaichi Mie (JP); Keisuke MORISHITA, Gyeonggi-do Seongnam-si (KR); Daichi SUGAWARA, Yokkaichi Mie (JP); Kenichi HAGA, Yokkaichi Mie (JP)

(73) Assignee: Kioxia Corporation, Tokyo (JP)

(21) Appl. No.: 19/323,647

(22) Filed: Sep. 9, 2025

(30) Foreign Application Priority Data
Mar. 21, 2025 (JP) 2025-046532

(51) Int. Cl. H10B 12/00

(52) U.S. Cl. CPC H10B 12/33; H10B 12/05

(57) ABSTRACT

A semiconductor device comprises: a first and second oxide semiconductor layer extending in a first direction, arranged in a second direction; and a first conductive layer extending in the second direction and facing parts of outer peripheral surfaces of the first and second oxide semiconductor layers. In a first cross section, the first conductive layer includes: a ring-like first portion provided separated by a first width from the outer peripheral surface of the first oxide semiconductor layer, and surrounding the first oxide semiconductor layer; and a ring-like second portion provided separated by the first width from the outer peripheral surface of the second oxide semiconductor layer, and surrounding the second oxide semiconductor layer. A part of a circle, ellipse, or racetrack shape circumscribing the first portion, and a part of a circle, ellipse, or racetrack shape circumscribing the second portion overlap.

### CROSS-REFERENCE TO RELATED APPLICATIONS

This application is based upon and claims the benefit of Japanese Patent Application No. 2025-046532, filed on Mar. 21, 2025, the entire contents of which are incorporated herein by reference.

### BACKGROUND

### Field

The present embodiments relate to semiconductor devices.

### Description of the Related Art

There is known a semiconductor device comprising: an oxide semiconductor layer; a first wiring facing the oxide semiconductor layer; and a gate insulating film provided between the oxide semiconductor layer and the first wiring.

### BRIEF DESCRIPTION OF THE DRAWINGS

FIG. 1 is a schematic circuit diagram showing a configuration of a part of a semiconductor device according to a first embodiment;

FIG. 2 is a schematic cross-sectional view showing a configuration of a part of the semiconductor device;

FIG. 3 is a schematic cross-sectional view showing a configuration of a part of the semiconductor device;

FIG. 4 is a schematic perspective view showing a configuration of a part of the semiconductor device;

FIG. 5 is a schematic plan view showing a configuration of a part of the semiconductor device;

FIG. 6 is a schematic plan view showing a configuration of a part of the semiconductor device;

FIG. 7 is a schematic plan view showing a configuration of a part of the semiconductor device;

FIG. 8 is a schematic plan view showing a configuration of a part of the semiconductor device;

FIG. 9 is a schematic plan view showing a configuration of a part of the semiconductor device;

FIG. 10 is a schematic perspective view showing a configuration of a part of the semiconductor device;

FIG. 11 is a schematic cross-sectional view showing a configuration of a part of the semiconductor device;

FIG. 12 is a schematic cross-sectional view showing a configuration of a part of the semiconductor device;

FIG. 13 is a schematic plan view showing a configuration of a part of the semiconductor device;

FIG. 14 is a schematic cross-sectional view for explaining a manufacturing method of same semiconductor device;

FIG. 15 is a schematic cross-sectional view for explaining same manufacturing method;

FIG. 16 is a schematic cross-sectional view for explaining same manufacturing method;

FIG. 17 is a schematic cross-sectional view for explaining same manufacturing method;

FIG. 18 is a schematic plan view for explaining same manufacturing method;

FIG. 19 is a schematic cross-sectional view for explaining same manufacturing method;

FIG. 20 is a schematic cross-sectional view for explaining same manufacturing method;

FIG. 21 is a schematic plan view for explaining same manufacturing method;

FIG. 22 is a schematic cross-sectional view for explaining same manufacturing method;

FIG. 23 is a schematic cross-sectional view for explaining same manufacturing method;

FIG. 24 is a schematic plan view for explaining same manufacturing method;

FIG. 25 is a schematic cross-sectional view for explaining same manufacturing method;

FIG. 26 is a schematic cross-sectional view for explaining same manufacturing method;

FIG. 27 is a schematic plan view for explaining same manufacturing method;

FIG. 28 is a schematic cross-sectional view for explaining same manufacturing method;

FIG. 29 is a schematic cross-sectional view for explaining same manufacturing method;

FIG. 30 is a schematic cross-sectional view for explaining same manufacturing method;

FIG. 31 is a schematic cross-sectional view for explaining same manufacturing method;

FIG. 32 is a schematic cross-sectional view for explaining same manufacturing method;

FIG. 33 is a schematic cross-sectional view for explaining same manufacturing method;

FIG. 34 is a schematic plan view for explaining same manufacturing method;

FIG. 35 is a schematic cross-sectional view for explaining same manufacturing method;

FIG. 36 is a schematic cross-sectional view for explaining same manufacturing method;

FIG. 37 is a schematic plan view for explaining same manufacturing method;

FIG. 38 is a schematic cross-sectional view for explaining same manufacturing method;

FIG. 39 is a schematic cross-sectional view for explaining same manufacturing method;

FIG. 40 is a schematic plan view for explaining same manufacturing method;

FIG. 41 is a schematic cross-sectional view for explaining same manufacturing method;

FIG. 42 is a schematic cross-sectional view for explaining same manufacturing method;

FIG. 43 is a schematic cross-sectional view for explaining same manufacturing method;

FIG. 44 is a schematic cross-sectional view for explaining same manufacturing method;

FIG. 45 is a schematic cross-sectional view for explaining same manufacturing method;

FIG. 46 is a schematic cross-sectional view for explaining same manufacturing method;

FIG. 47 is a schematic cross-sectional view for explaining same manufacturing method;

FIG. 48 is a schematic cross-sectional view for explaining same manufacturing method;

FIG. 49 is a schematic cross-sectional view for explaining same manufacturing method;

FIG. 50 is a schematic cross-sectional view for explaining same manufacturing method;

FIG. 51 is a schematic cross-sectional view for explaining same manufacturing method;

FIG. 52 is a schematic cross-sectional view for explaining same manufacturing method;

FIG. 53 is a schematic cross-sectional view showing a configuration of a part of modified example 1 of the semiconductor device according to the first embodiment;

FIG. 54 is a schematic plan view showing a configuration of a part of same modified example;

FIG. 55 is a schematic cross-sectional view for explaining a manufacturing method of same modified example;

FIG. 56 is a schematic cross-sectional view for explaining same manufacturing method;

FIG. 57 is a schematic plan view showing a configuration of a part of modified example 2 of the semiconductor device according to the first embodiment;

FIG. 58 is a schematic perspective view showing a configuration of a part of same modified example;

FIG. 59 is a schematic cross-sectional view showing a configuration of a part of same modified example;

FIG. 60 is a schematic plan view showing a configuration of a part of modified example 3 of the semiconductor device according to the first embodiment;

FIG. 61 is a schematic perspective view showing a configuration of a part of same modified example;

FIG. 62 is a schematic cross-sectional view showing a configuration of a part of same modified example;

FIG. 63 is a schematic cross-sectional view showing a configuration of a part of a semiconductor device according to a second embodiment;

FIG. 64 is a schematic cross-sectional view showing a configuration of a part of the semiconductor device;

FIG. 65 is a schematic cross-sectional view showing a configuration of a part of the semiconductor device;

FIG. 66 is a schematic cross-sectional view showing a configuration of a part of the semiconductor device;

FIG. 67 is a schematic cross-sectional view for explaining a first manufacturing method of same semiconductor device;

FIG. 68 is a schematic cross-sectional view for explaining same manufacturing method;

FIG. 69 is a schematic plan view for explaining same manufacturing method;

FIG. 70 is a schematic cross-sectional view for explaining same manufacturing method;

FIG. 71 is a schematic cross-sectional view for explaining same manufacturing method;

FIG. 72 is a schematic plan view for explaining same manufacturing method;

FIG. 73 is a schematic cross-sectional view for explaining same manufacturing method;

FIG. 74 is a schematic cross-sectional view for explaining same manufacturing method;

FIG. 75 is a schematic plan view for explaining same manufacturing method;

FIG. 76 is a schematic cross-sectional view for explaining same manufacturing method;

FIG. 77 is a schematic cross-sectional view for explaining same manufacturing method;

FIG. 78 is a schematic plan view for explaining same manufacturing method;

FIG. 79 is a schematic cross-sectional view for explaining same manufacturing method;

FIG. 80 is a schematic cross-sectional view for explaining same manufacturing method;

FIG. 81 is a schematic plan view for explaining same manufacturing method;

FIG. 82 is a schematic cross-sectional view for explaining same manufacturing method;

FIG. 83 is a schematic cross-sectional view for explaining same manufacturing method;

FIG. 84 is a schematic plan view for explaining same manufacturing method;

FIG. 85 is a schematic cross-sectional view for explaining same manufacturing method;

FIG. 86 is a schematic cross-sectional view for explaining same manufacturing method;

FIG. 87 is a schematic plan view for explaining same manufacturing method;

FIG. 88 is a schematic cross-sectional view for explaining same manufacturing method;

FIG. 89 is a schematic cross-sectional view for explaining same manufacturing method;

FIG. 90 is a schematic plan view for explaining same manufacturing method;

FIG. 91 is a schematic cross-sectional view for explaining same manufacturing method;

FIG. 92 is a schematic cross-sectional view for explaining a manufacturing method 2 of same semiconductor device;

FIG. 93 is a schematic cross-sectional view for explaining same manufacturing method;

FIG. 94 is a schematic plan view for explaining same manufacturing method;

FIG. 95 is a schematic cross-sectional view for explaining same manufacturing method;

FIG. 96 is a schematic cross-sectional view for explaining same manufacturing method;

FIG. 97 is a schematic plan view for explaining same manufacturing method;

FIG. 98 is a schematic cross-sectional view for explaining same manufacturing method;

FIG. 99 is a schematic cross-sectional view for explaining same manufacturing method;

FIG. 100 is a schematic plan view for explaining same manufacturing method;

FIG. 101 is a schematic cross-sectional view for explaining same manufacturing method;

FIG. 102 is a schematic cross-sectional view for explaining same manufacturing method;

FIG. 103 is a schematic plan view for explaining same manufacturing method;

FIG. 104 is a schematic cross-sectional view for explaining same manufacturing method;

FIG. 105 is a schematic cross-sectional view for explaining same manufacturing method;

FIG. 106 is a schematic plan view for explaining same manufacturing method;

FIG. 107 is a schematic cross-sectional view showing a configuration of a part of a modified example of the semiconductor device according to the second embodiment;

FIG. 108 is a schematic cross-sectional view showing a configuration of a part of a semiconductor device according to a third embodiment;

FIG. 109 is a schematic plan view showing a configuration of a part of the semiconductor device;

FIG. 110 is a schematic perspective view showing a configuration of a part of the semiconductor device;

FIG. 111 is a schematic cross-sectional view for explaining a manufacturing method of same semiconductor device;

FIG. 112 is a schematic cross-sectional view for explaining same manufacturing method;

FIG. 113 is a schematic plan view for explaining same manufacturing method;

FIG. 114 is a schematic cross-sectional view for explaining same manufacturing method;

FIG. 115 is a schematic cross-sectional view for explaining same manufacturing method;

FIG. 116 is a schematic plan view for explaining same manufacturing method;

FIG. 117 is a schematic cross-sectional view for explaining same manufacturing method;

FIG. 118 is a schematic cross-sectional view for explaining same manufacturing method;

FIG. 119 is a schematic cross-sectional view for explaining same manufacturing method;

FIG. 120 is a schematic cross-sectional view for explaining same manufacturing method;

FIG. 121 is a schematic cross-sectional view for explaining same manufacturing method;

FIG. 122 is a schematic cross-sectional view for explaining same manufacturing method;

FIG. 123 is a schematic cross-sectional view for explaining same manufacturing method;

FIG. 124 is a schematic cross-sectional view for explaining same manufacturing method;

FIG. 125 is a schematic cross-sectional view for explaining same manufacturing method;

FIG. 126 is a schematic cross-sectional view for explaining same manufacturing method;

FIG. 127 is a schematic cross-sectional view for explaining same manufacturing method;

FIG. 128 is a schematic cross-sectional view for explaining same manufacturing method;

FIG. 129 is a schematic plan view for explaining same manufacturing method;

FIG. 130 is a schematic cross-sectional view for explaining same manufacturing method;

FIG. 131 is a schematic cross-sectional view for explaining same manufacturing method;

FIG. 132 is a schematic plan view for explaining same manufacturing method; and

FIG. 133 is a schematic cross-sectional view showing a configuration of a part of the semiconductor device according to the third embodiment.

### DETAILED DESCRIPTION

A semiconductor device according to one embodiment comprises: a substrate; a first oxide semiconductor layer and a second oxide semiconductor layer which extend in a first direction intersecting a surface of the substrate, are arranged in a second direction intersecting the first direction, and include a first metal element and oxygen (O); a first conductive layer which extends in the second direction and faces a part of an outer peripheral surface of the first oxide semiconductor layer and a part of an outer peripheral surface of the second oxide semiconductor layer; a first gate insulating layer provided between the first oxide semiconductor layer and the first conductive layer; and a second gate insulating layer provided between the second oxide semiconductor layer and the first conductive layer. In a first cross section which extends in the second direction and a third direction intersecting the first direction and the second direction, and includes the first oxide semiconductor layer, the second oxide semiconductor layer, and the first conductive layer, the first conductive layer includes: a ring-like first portion which is provided separated by a first width from the outer peripheral surface of the first oxide semiconductor layer, and surrounds the first oxide semiconductor layer; and a ring-like second portion which is provided separated by the first width from the outer peripheral surface of the second oxide semiconductor layer, and surrounds the second oxide semiconductor layer. A part of a circle, ellipse, or racetrack shape circumscribing the first portion, and a part of a circle, ellipse, or racetrack shape circumscribing the second portion overlap.

Next, semiconductor devices according to embodiments will be described in detail with reference to the drawings. Note that the following embodiments are merely examples, and are not shown with the intention of limiting the present invention. Moreover, the following drawings are schematic, and, for convenience of description, parts of configurations, and so on, thereof will sometimes be omitted. Moreover, portions that are common to a plurality of embodiments will be assigned with the same symbols, and descriptions thereof sometimes omitted.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been connected in series, the first transistor is still “electrically connected” to the third transistor even when the second transistor is in an OFF state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction lying along a certain plane will sometimes be referred to as a first direction, a direction intersecting the first direction along this certain plane will sometimes be referred to as a second direction, and a direction intersecting this certain plane will sometimes be referred to as a third direction. These first direction, second direction, and third direction may correspond to any of the X-direction, the Y-direction, and the Z-direction, but need not do so.

Moreover, in the present specification, expressions such as “above” or “below” will be defined with reference to the substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting the X-direction or the Y-direction will be referred to as a side surface, an outer peripheral surface, and so on.

### First Embodiment

### [Circuit Configuration]

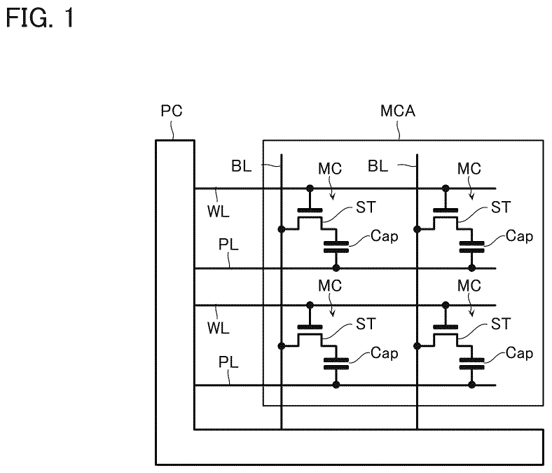

FIG. 1 is a schematic circuit diagram showing a configuration of a part of a semiconductor device according to a first embodiment. The semiconductor device according to the first embodiment comprises a memory cell array MCA and a peripheral circuit PC of the kind shown in FIG. 1, for example.

The memory cell array MCA comprises: a plurality of bit lines BL; a plurality of word lines WL; a plurality of plate lines PL; and a plurality of memory cells MC connected to these plurality of bit lines BL, plurality of word lines WL, and plurality of plate lines PL. The plurality of memory cells MC connected to one word line WL are each connected to mutually differing bit lines BL. Moreover, the plurality of memory cells MC connected to one bit line BL are each connected to mutually differing word lines WL.

The memory cells MC each comprise a select transistor ST and a capacitor Cap that are connected in series between the bit line BL and the plate line PL.

The select transistor ST is a field effect type transistor which comprises a semiconductor layer functioning as a channel region, and comprises a gate insulating layer and a gate electrode. The gate electrodes of the select transistors ST are each connected with the word lines WL.

The capacitor Cap is a capacitor which comprises a pair of electrodes and an insulating film. The capacitor Cap functions as a memory portion.

The peripheral circuit PC comprises, for example, the likes of: a voltage generating circuit that generates operating voltages to be outputted to voltage supply lines; a decode circuit that makes a desired voltage supply line electrically conductive with each wiring (bit line BL, word line WL, and plate line PL) in the memory cell array MCA; and a sense amplifier circuit that detects current or voltage of the bit line BL.

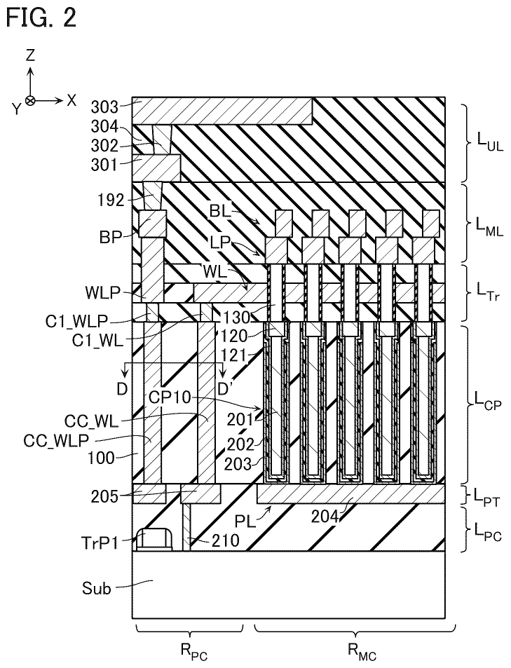

FIG. 2 is a schematic cross-sectional view showing a configuration of a part of the semiconductor device. As shown in FIG. 2, the semiconductor device according to the first embodiment comprises: a substrate Sub; a transistor layer L_{Tr} separated in the Z-direction from the substrate Sub; a wiring layer L_{ML} provided above the transistor layer L_{Tr}; a wiring layer L_{UL} provided above the wiring layer L_{ML}; a capacitor layer L_{CP} provided below the transistor layer L_{Tr}; a plate line layer L_{PT} provided below the capacitor layer L_{CP}; and a peripheral circuit layer L_{PC} provided on the substrate Sub below the plate line layer L_{PT}. The substrate Sub includes P-type silicon (Si) including a P-type impurity such as boron (B), for example.

In addition, as shown in FIG. 2, the semiconductor device according to the first embodiment comprises a memory region R_{MC} and a peripheral region R_{PC} that are provided on the substrate Sub.

### [Structure of Memory Region R_{MC}]

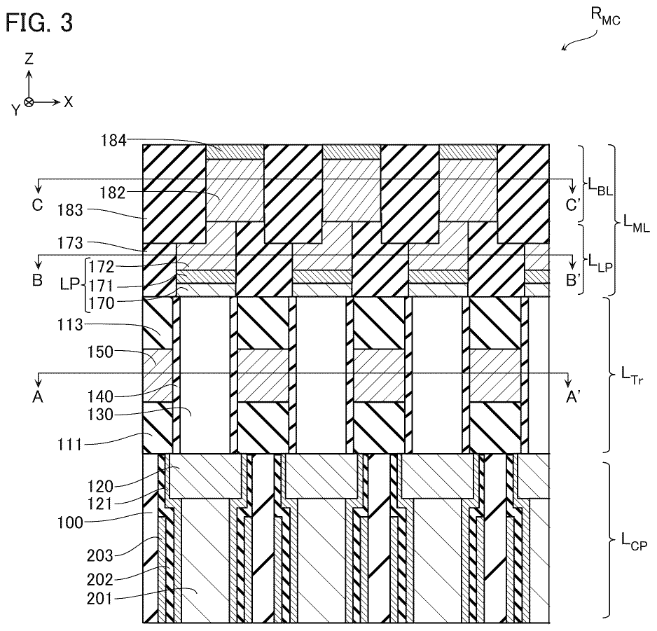

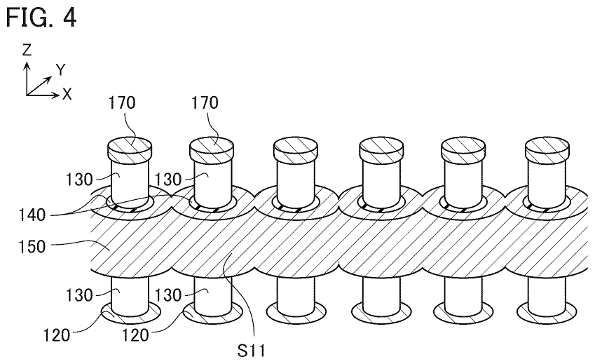

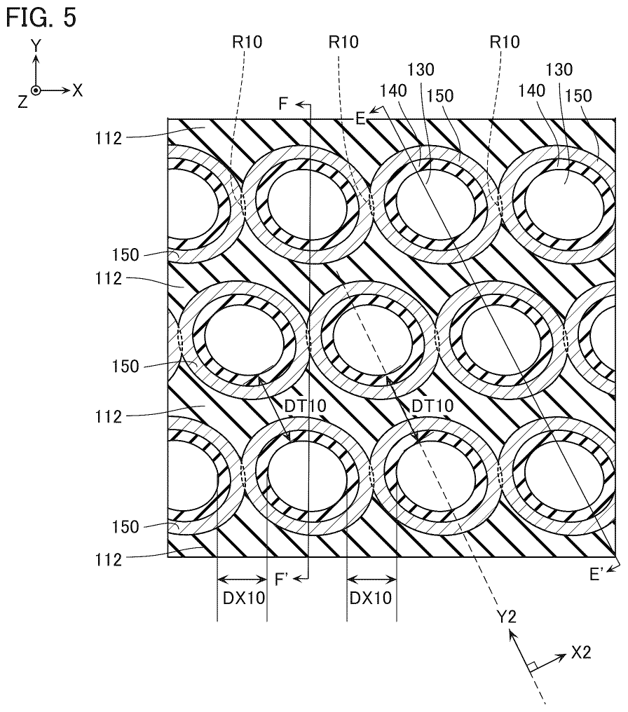

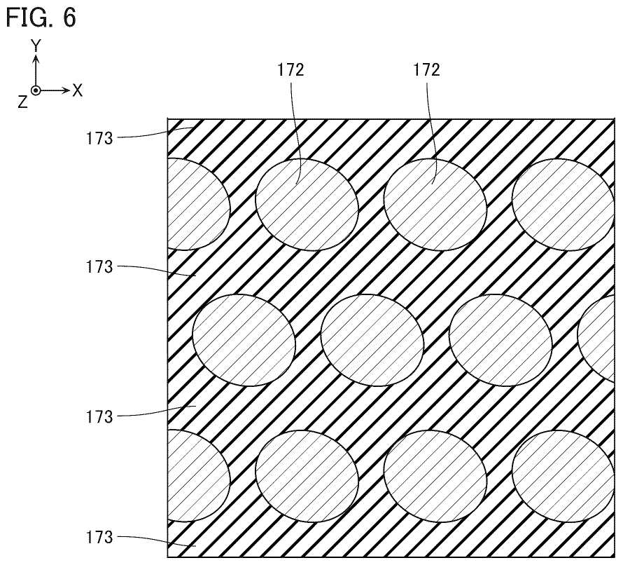

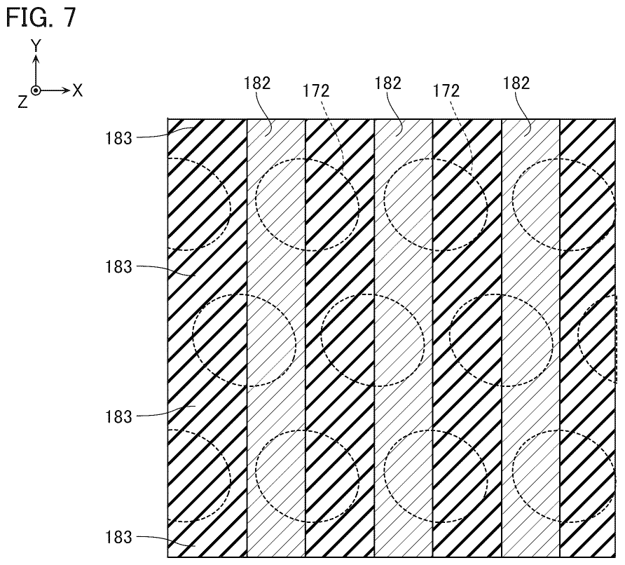

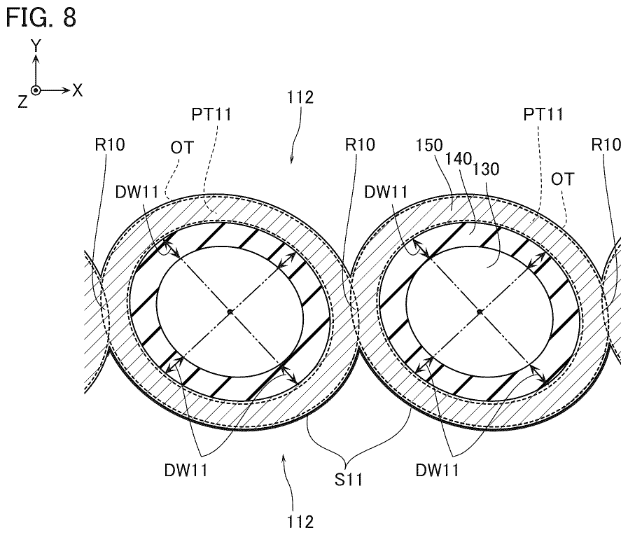

Next, a structure of the memory region R_{MC} will be described with reference to FIGS. 2 to 8. FIGS. 3 to 8 are schematic cross-sectional views, plan views, and perspective views showing a configuration of a part of the semiconductor device according to the first embodiment. FIG. 3 shows a configuration of a part of the memory region R_{MC}. FIG. 4 shows a structure of the transistor layer L_{Tr}, and a connecting portion to the transistor layer L_{Tr}. Note that in FIG. 4, for convenience of description, illustration of parts of an insulating layer 140 provided in portions above and below a conductive layer 150, is omitted. FIG. 5 is a schematic plan view in which the configuration shown in FIG. 3 has been cut along the line A-A′ and viewed along a direction of the arrows. FIG. 6 is a schematic plan view in which the configuration shown in FIG. 3 has been cut along the line B-B′ and viewed along a direction of the arrows. FIG. 7 is a schematic plan view in which the configuration shown in FIG. 3 has been cut along the line C-C′ and viewed along a direction of the arrows. Note that in FIG. 7, parts of the configurations shown in FIG. 6 are shown by broken lines. FIG. 8 is a schematic plan view in which a part of the configuration shown in FIG. 5 has been enlarged.

As shown in FIG. 3, for example, the transistor layer L_{Tr} of the memory region R_{MC} comprises: an insulating layer 111 provided on an upper surface of the capacitor layer L_{CP}; and an insulating layer 113 provided above the insulating layer 111. Moreover, as shown in FIG. 5, for example, the transistor layer L_{Tr} of the memory region R_{MC} comprises a plurality of insulating layers 112 and a plurality of conductive layers 150 which are provided between the insulating layer 111 and the insulating layer 113, and are arranged alternately in the Y-direction. In addition, as shown in FIGS. 4 and 5, for example, the transistor layer L_{Tr} of the memory region R_{MC} comprises: pluralities of semiconductor layers 130 arranged in the X-direction correspondingly to the conductive layers 150 extending in the X-direction; and an insulating layer 140 provided between each of the semiconductor layers 130 and the conductive layers 150.

Note that as shown in FIG. 5, for example, positions in the X-direction of the plurality of semiconductor layers 130 arranged correspondingly to one of two conductive layers 150 adjacent in the Y-direction, and positions in the X-direction of the plurality of semiconductor layers 130 arranged correspondingly to the other of the two conductive layers 150 adjacent in the Y-direction, may differ from each other.

Moreover, as shown in FIG. 5, for example, a direction in which the semiconductor layers 130 are arranged correspondingly to different conductive layers 150 will hereafter sometimes be referred to as a Y2 direction (FIG. 5). The Y2 direction is a different direction from the X-direction. The Y2 direction may be different from the Y-direction, or may be the same as the Y-direction. Moreover, a direction intersecting the Y2 direction and the Z-direction will hereafter sometimes be referred to as an X2 direction (FIG. 5).

The insulating layer 111, the insulating layer 112, and the insulating layer 113 include the likes of silicon oxide (SiO₂), for example.

The semiconductor layer 130 extends in the Z-direction and has a substantially circular column-like shape, for example. The semiconductor layer 130, which is an oxide semiconductor, functions as the channel region of the select transistor ST (FIG. 1), for example. The semiconductor layer 130 includes, for example: at least one element selected from a metal element group GP1; and oxygen (O).

The metal element group GP1 includes indium (In), gallium (Ga), aluminum (Al), zinc (Zn), tin (Sn), titanium (Ti), tungsten (W), and molybdenum (Mo).

The semiconductor layer 130 may include indium (In), zinc (Zn), and oxygen (O), may include indium (In), gallium (Ga), and oxygen (O), may include gallium (Ga), zinc (Zn), and oxygen (O), may include indium (In), gallium (Ga), zinc (Zn), and oxygen (O), may include indium (In), gallium (Ga), tin (Sn), and oxygen (O), or may include indium (In), tungsten (W), and oxygen (O), for example.

As shown in FIG. 5, for example, in an XY cross section including the plurality of semiconductor layers 130 and the plurality of conductive layers 150, a closest distance between an outer peripheral surface of one of two semiconductor layers 130 arranged in the X-direction and an outer peripheral surface of the other of the two semiconductor layers 130 arranged in the X-direction, is a width DX10. Moreover, a closest distance between an outer peripheral surface of one of two semiconductor layers 130 arranged in the Y2 direction and an outer peripheral surface of the other of the two semiconductor layers 130 arranged in the Y2 direction, is a width DT10. Width DT10 is greater than width DX10.

The insulating layer 140 extends in the Z-direction and has a substantially cylindrical shape, for example. The insulating layer 140 is provided on at least a part of the outer peripheral surface of the semiconductor layer 130, for example. The insulating layer 140 functions as the gate insulating layer of the select transistor ST (FIG. 1), for example. The insulating layer 140 includes the likes of silicon oxide (SiO₂), silicon nitride (SiN), and another high dielectric constant insulating layer, for example. The insulating layer 140 may be a stacked structure including at least two of silicon oxide (SiO₂), silicon nitride (SiN), and another high dielectric constant insulating layer.

As shown in FIGS. 3 and 4, for example, the conductive layer 150 faces a part of the outer peripheral surface of the semiconductor layer 130. As shown in FIG. 4, for example, the conductive layer 150 is provided with substantially cylindrical portions ranging in the X-direction, that surround parts of the semiconductor layer 130 and the insulating layer 140. A surface S11 (FIGS. 4 and 8) on at least one side in the Y-direction of the conductive layer 150 does not include a planar portion, but is provided with a ranging curved surface.

In an XY cross section including two semiconductor layers 130 adjacent in the X-direction of the kind shown in FIG. 8, for example, the conductive layer 150 includes ring-like portions PT11 which are provided separated by a width DW11 from the outer peripheral surfaces of the semiconductor layers 130, and each surround the semiconductor layers 130. The width DW11 corresponds to a film thickness of the insulating layer 140, for example. In the XY cross section shown in FIG. 8, a part of an outer contact line OT circumscribing one of the portions PT11 and a part of an outer contact line OT circumscribing the other of the portions PT11, overlap. The outer contact line OT is the likes of a circle, ellipse, or racetrack shape, for example.

Moreover, in the XY cross section shown in FIG. 8, parts of the portions PT11 arranged in the X-direction overlap. In FIGS. 5 and 8, portions where the portions PT11 arranged in the X-direction overlap are each illustrated as a region R10. Note that a portion other than the portion included in the region R10, of the outer peripheral surface of the portion PT11 contacts the insulating layer 112.

The conductive layer 150 functions as the gate electrodes of a plurality of the select transistors ST arranged in the X-direction, and as the word line WL of the memory cell array MCA (FIG. 1), for example. The conductive layer 150 may be, for example, of tungsten (W), molybdenum (Mo), ruthenium (Ru), cobalt (Co), titanium nitride (TiN), or the like, or may include, for example, a stacked structure including: at least one of tungsten (W), molybdenum (Mo), ruthenium (Ru), and cobalt (Co); and titanium nitride (TiN).

As shown in FIG. 3, for example, the wiring layer L_{ML} of the memory region R_{MC} comprises: a plug layer L_{LP} provided on an upper surface of the transistor layer L_{Tr}; and a bit line layer L_{BL} provided on an upper surface of the plug layer L_{LP}.

As shown in FIGS. 3 and 6, for example, the plug layer L_{LP} comprises a conductive layer 170, a conductive layer 171, and a conductive layer 172 which are provided in order on the upper surface of the transistor layer L_{Tr} at a position corresponding to the semiconductor layer 130. The conductive layer 170, conductive layer 171, and the conductive layer 172 are each electrically connected to the semiconductor layer 130. Note that hereafter, a structure including the conductive layer 170, the conductive layer 171, and the conductive layer 172 will sometimes be referred to as a plug LP. Note that configuration of the plug LP is appropriately adjustable, and that, for example, any of the conductive layer 170, the conductive layer 171, and the conductive layer 172 may be omitted.

As shown in FIGS. 3 and 6, for example, a plurality of the plugs LP, each extending in the Z-direction, are provided arranged in the X-direction and the Y-direction. The plug LP functions as a source electrode of the select transistor ST, for example. An insulating layer 173 of the likes of silicon oxide (SiO₂) is provided between each of the plurality of plugs LP.

The conductive layer 170 includes, for example: at least one element selected from a metal element group GP2; and oxygen (O). The metal element group GP2 includes indium (In), gallium (Ga), zinc (Zn), magnesium (Mg), aluminum (Al), manganese (Mn), tin (Sn), niobium (Nb), titanium (Ti), tantalum (Ta), calcium (Ca), tungsten (W), and molybdenum (Mo). The conductive layer 170 may be of the likes of indium tin oxide (InSnO), for example. Moreover, the conductive layer 170 may include a stacked film including at least one of these materials.

The conductive layer 171 includes the likes of titanium nitride (TiN) or titanium oxide (TiO), for example. Moreover, the conductive layer 171 may include a stacked film including at least one of these materials.

The conductive layer 172 includes the likes of tungsten (W), aluminum (Al), or molybdenum (Mo), for example. Moreover, the conductive layer 172 may include a stacked film including at least one of these materials.

As shown in FIGS. 3 and 7, for example, the bit line layer L_{BL} comprises a conductive layer 182 and a conductive layer 184 which are provided in order on a part of the upper surface of the plug layer L_{LP} at a position corresponding to the conductive layer 172. The conductive layer 182 and the conductive layer 184 are electrically connected to a plurality of the conductive layers 172 arranged in the Y-direction correspondingly to the conductive layer 182 and the conductive layer 184 (FIG. 7). Note that configurations of the conductive layer 182 and the conductive layer 184 are appropriately adjustable, and that, for example, either of the conductive layer 182 and the conductive layer 184 may be omitted.

As shown in FIGS. 3 and 7, for example, a plurality of structures including the conductive layer 182 and the conductive layer 184, each extending in the Y-direction, are provided arranged in the X-direction. The conductive layer 182 and the conductive layer 184 function as the bit line BL of the memory cell array MCA (FIG. 1), for example. An insulating layer 183 of the likes of silicon oxide (SiO₂) is provided between these structures arranged in the X-direction.

The conductive layer 182 includes a metal element such as tungsten (W), aluminum (Al), or molybdenum (Mo), for example.

The conductive layer 184 includes the likes of titanium nitride (TiN), for example.

As shown in FIGS. 2 and 3, for example, the capacitor layer L_{CP} of the memory region R_{MC} comprises: a plurality of conductive layers 120 provided correspondingly to the plurality of semiconductor layers 130, and each connected to lower ends of the plurality of semiconductor layers 130; a plurality of conductive layers 201 provided correspondingly to the plurality of conductive layers 120, and each connected to lower ends of the plurality of conductive layers 120; and a plurality of conductive layers 121 provided on outer peripheral surfaces of the plurality of conductive layers 120 and on outer peripheral surfaces and lower surfaces of the plurality of conductive layers 201. In addition, the capacitor layer L_{CP} comprises: an insulating layer 202 provided on an outer peripheral surface and lower surface of the conductive layer 121; and a conductive layer 203 provided on an outer peripheral surface and lower surface of the insulating layer 202 (FIG. 3). Note that in the description below, these configurations realizing the capacitor Cap (FIG. 1) provided in the capacitor layer L_{CP} of the memory region R_{MC} will sometimes be referred to as a “capacitor structure CP10”. The capacitor structure CP10 includes the conductive layer 120, the conductive layer 121, the conductive layer 201, the insulating layer 202, and the conductive layer 203, for example. An insulating layer 100 of the likes of silicon oxide (SiO₂), for example, is provided between a plurality of the capacitor structures CP10.

The conductive layer 120 functions as a drain electrode of the select transistor ST (FIG. 1), and as a part of one electrode of the capacitor Cap (FIG. 1), for example. The conductive layer 120, which is substantially circular in XY cross section, may have a plug shape. The conductive layer 120 includes a similar material to the conductive layer 170, for example. The conductive layer 120 may be of the likes of indium tin oxide (InSnO), for example.

The conductive layer 121 functions as a part of one electrode of the capacitor Cap (FIG. 1), for example. The conductive layer 121 may be of the likes of titanium nitride (TiN), for example.

The conductive layer 201 functions as a part of one electrode of the capacitor Cap (FIG. 1), for example. The conductive layer 201 includes the likes of a stacked structure of titanium nitride (TiN) and tungsten (W), for example.

The insulating layer 202 functions as an inter-electrode insulating layer of the capacitor Cap (FIG. 1). The insulating layer 202 includes the likes of aluminum oxide (AlO), for example. The insulating layer 202 may be of silicon oxide (SiO₂) or another insulating metal oxide, for example.

The conductive layer 203 functions as the other electrode of the capacitor Cap (FIG. 1), for example. The conductive layer 203 includes the likes of a stacked structure of titanium nitride (TiN) and tungsten (W), for example.

As shown in FIG. 2, for example, the plate line layer L_{PT} of the memory region R_{MC} comprises a conductive layer 204 which is provided on a lower surface of the capacitor layer L_{CP}. The conductive layer 204 is electrically connected to a plurality of the conductive layers 203. The conductive layer 204 functions as the plate line PL (FIG. 1), for example. The conductive layer 204 may include the likes of tungsten (W), or a stacked structure of titanium nitride (TiN) and tungsten (W), for example.

### [Structure of Peripheral Region R_{PC}]

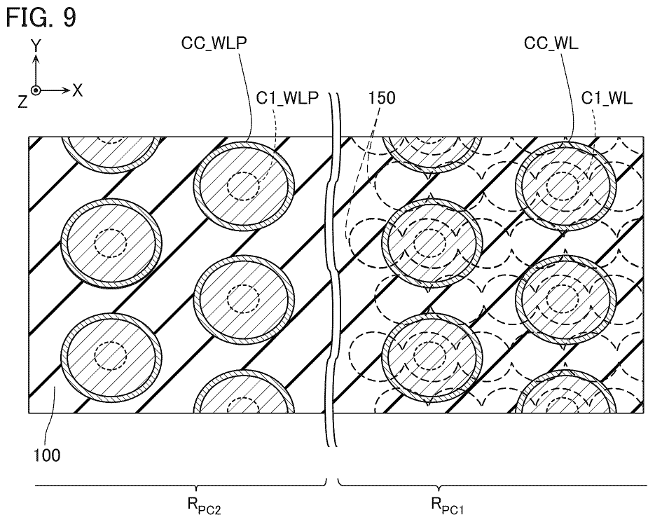

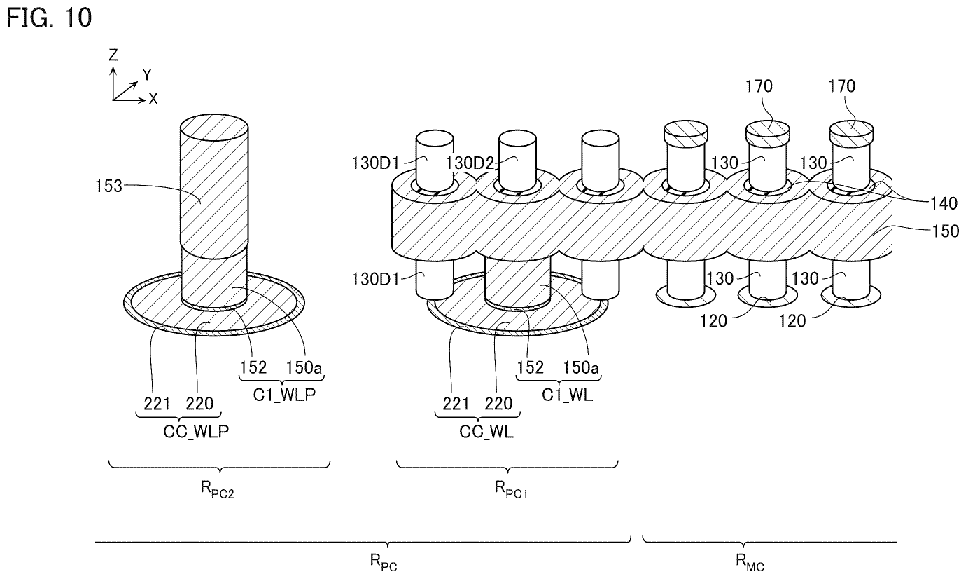

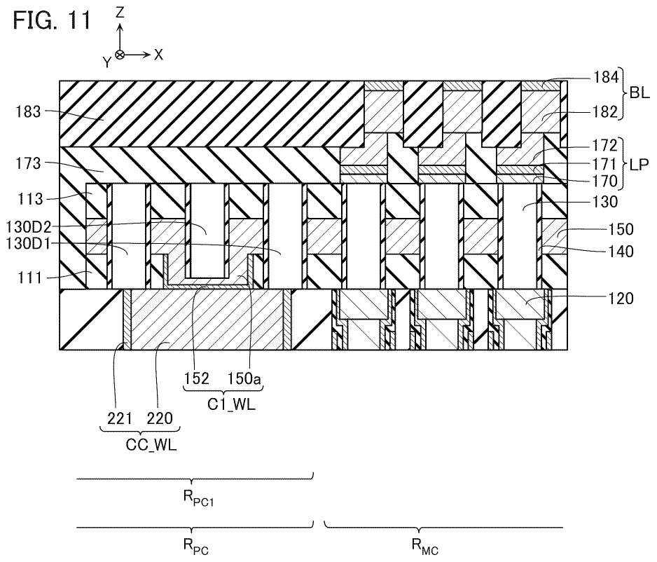

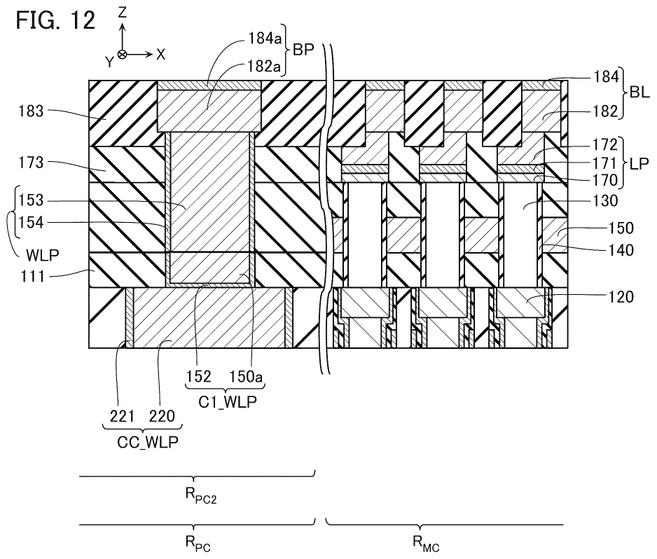

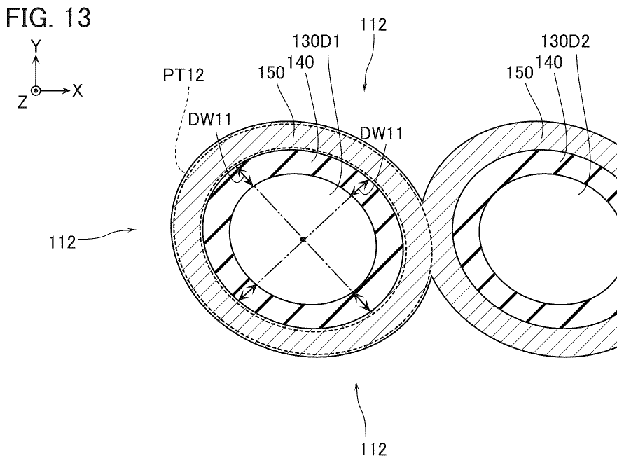

Next, a structure of the peripheral region R_{PC} (FIG. 2) will be described with reference to FIG. 2, and 9 to 13. FIGS. 9 to 13 are schematic cross-sectional views, plan views, and perspective views showing a configuration of a part of the semiconductor device according to the first embodiment. FIG. 9 is a schematic plan view in which the configuration shown in FIG. 2 has been cut along the line D-D′ and viewed along a direction of the arrows. Note that in FIG. 9, in order to show positional relationships, parts of the conductive layers 150 and later-mentioned electrodes C1_WL, C1_WLP not appearing in same cross section, are shown by broken lines. FIG. 10 shows a structure of the memory region R_{MC} and peripheral region R_{PC}. FIG. 11 shows a structure of a part of a region R_{PC1}. FIG. 12 shows a structure of a part of a region R_{PC2}. FIG. 13 shows a structure of an end portion of the conductive layer 150.

As shown in FIG. 2, for example, the plate line layer L_{PT} of the peripheral region R_{PC} comprises a plurality of conductive layers 205. The conductive layer 205 may include a similar material to the conductive layer 204, for example.

As shown in FIG. 2, for example, the peripheral circuit layer L_{PC} of the peripheral region R_{PC} comprises: a plurality of transistors TrP1 provided on the substrate Sub; and a plurality of electrodes 210 connected to the plurality of transistors TrP1. The plurality of electrodes 210 have their upper ends connected to the conductive layers 205, for example. The plurality of electrodes 210 have their lower ends connected to a source region, a drain region, a gate electrode, and so on, of the plurality of transistors TrP1, for example. The plurality of transistors TrP1 configure the peripheral circuit PC (FIG. 1), for example.

The wiring layer L_{ML} of the peripheral region R_{PC} comprises: a conductive layer BP provided in the same layer as the bit line BL; and an electrode 192 connected to an upper surface of the conductive layer BP.

The conductive layer BP (FIG. 12) includes conductive layers 182a, 184a that include similar materials to the conductive layers 182, 184, for example.

The electrode 192 extends in the Z-direction as shown in FIG. 2, and has a substantially circular column-like shape, for example. The electrode 192 may include the likes of tungsten (W), or a stacked structure of titanium nitride (TiN) and tungsten (W), for example.

As shown in FIG. 2, for example, the wiring layer L_{UL} comprises: a wiring 301 provided on an upper surface of the wiring layer L_{ML}; a wiring 302 provided connected to the wiring 301 on an upper surface of the wiring 301; and a wiring 303 provided connected to the wiring 302 on an upper surface of the wiring 302. An insulating layer 304 of the likes of silicon oxide (SiO₂), for example, is provided between the wiring 301, the wiring 302, and the wiring 303.

The wiring 301, the wiring 302, and the wiring 303 function as a wiring for applying a voltage and a current to the peripheral circuit PC and the bit line BL, for example. The wiring 301, the wiring 302, and the wiring 303 include the likes of copper (Cu), tungsten (W), or aluminum (Al), for example.

As shown in FIGS. 2 and 9, for example, the capacitor layer L_{CP} of the peripheral region R_{PC} comprises a plurality of through electrodes CC_WL and a plurality of through electrodes CC_WLP extending in the Z-direction. Note that hereafter, a region provided with the through electrodes CC_WL, of the peripheral region R_{PC} will sometimes be referred to as a region R_{PC1}, and a region provided with the through electrodes CC_WLP, of the peripheral region R_{PC} will sometimes be referred to as a region R_{PC2}. The region R_{PC1} is provided between the region R_{PC2} and the memory region R_{MC} (FIG. 10).

As shown in FIG. 2, for example, the through electrode CC_WL has an upper end connected to a later-mentioned electrode C1_WL of the transistor layer L_{Tr}, and has a lower end electrically connected to a part of the plurality of conductive layers 205 in the plate line layer L_{PT} (FIG. 2). As shown in FIGS. 10 and 11, for example, the through electrode CC_WL includes a conductive layer 220 of the likes of tungsten (W), and a conductive layer 221 of the likes of titanium nitride (TiN).

As shown in FIG. 2, for example, the through electrode CC_WLP has an upper end connected to a later-mentioned electrode C1_WLP of the transistor layer L_{Tr}, and has a lower end electrically connected to a part of the plurality of conductive layers 205 in the plate line layer L_{PT} (FIG. 2). As shown in FIGS. 10 and 12, for example, the through electrode CC_WLP includes the conductive layer 220 and the conductive layer 221.

### [Structure of Region R_{PC1}]

The transistor layer L_{Tr} of the region R_{PC1} (FIG. 11) comprises parts of the insulating layers 111, 112, 113 and the conductive layer 150 similar to in the transistor layer L_{Tr} of the memory region R_{MC} (FIG. 3). Note that one end portion in the X-direction of the conductive layer 150 is provided in the transistor layer L_{Tr} of the region R_{PC1}. In addition, the transistor layer L_{Tr} of the region R_{PC1} comprises: semiconductor layers 130D1, 130D2 arranged in the X-direction correspondingly to the conductive layer 150; the insulating layer 140 provided between each of the semiconductor layers 130D1, 130D2 and the conductive layer 150; and an electrode C1_WL provided between the conductive layer 150 and the through electrode CC_WL.

The semiconductor layers 130D1, 130D2 are basically provided similarly to the semiconductor layers 130, include a similar material to the semiconductor layers 130, and are arranged in the X-direction with the semiconductor layers 130. However, the semiconductor layers 130D1, 130D2 are provided as dummy structures, and do not function as the channel region of the select transistor ST (FIG. 1).

The electrode C1_WL surrounds a part of a side surface of the semiconductor layer 130D2, and a lower surface of the semiconductor layer 130D2. As shown in FIGS. 10 and 11, for example, the electrode C1_WL includes: a conductive layer 150a including a similar material to the conductive layer 150; and a conductive layer 152 of the likes of titanium nitride (TiN). The conductive layer 150a may be formed continuously with the conductive layer 150. The conductive layer 150 and the through electrode CC_WL are electrically connected via the electrode C1_WL.

FIG. 13 shows: the semiconductor layer 130D1 provided furthest to an end in the X-direction in the region R_{PC1}; and an end portion in the X-direction of the conductive layer 150 facing the semiconductor layer 130D1. In the XY cross section shown in FIG. 13, for example, the conductive layer 150 is provided separated by the width DW11 from an outer peripheral surface of the semiconductor layer 130D1, and includes a ring-like portion PT12 surrounding the semiconductor layer 130D1. The portion PT12 is at least a part of the end portion in the X-direction of the conductive layer 150. A part of an outer peripheral surface of the portion PT12 contacts the insulating layer 112.

### [Structure of Region R_{PC2}]

The transistor layer L_{Tr} of the region R_{PC2} (FIG. 12) comprises an electrode WLP and an electrode C1_WLP.

The electrode WLP has an upper end connected to the conductive layer BP, and has a lower end connected to the electrode C1_WLP, for example. The electrode WLP includes a conductive layer 153 of the likes of tungsten (W), and a conductive layer 154 of the likes of titanium nitride (TiN).

The electrode C1_WLP is provided between the electrode WLP and the through electrode CC_WLP. The electrode WLP and the through electrode CC_WLP are electrically connected via the electrode C1_WLP. The electrode C1_WLP includes the conductive layer 150a and the conductive layer 152.

### [Manufacturing Method of First Embodiment]

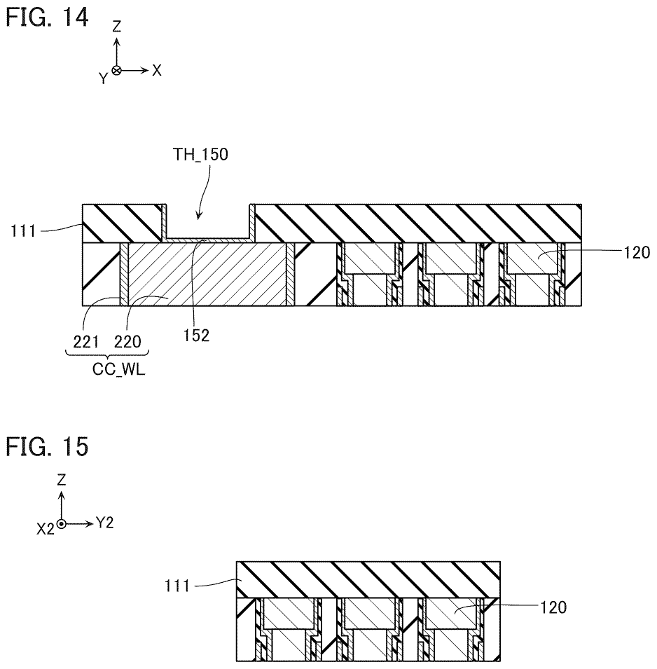

Next, a manufacturing method the semiconductor device according to the present embodiment will be described with reference to FIGS. 14 to 52. FIGS. 14 to 52 are schematic cross-sectional views and plan views for explaining the manufacturing method of the semiconductor device according to the first embodiment.

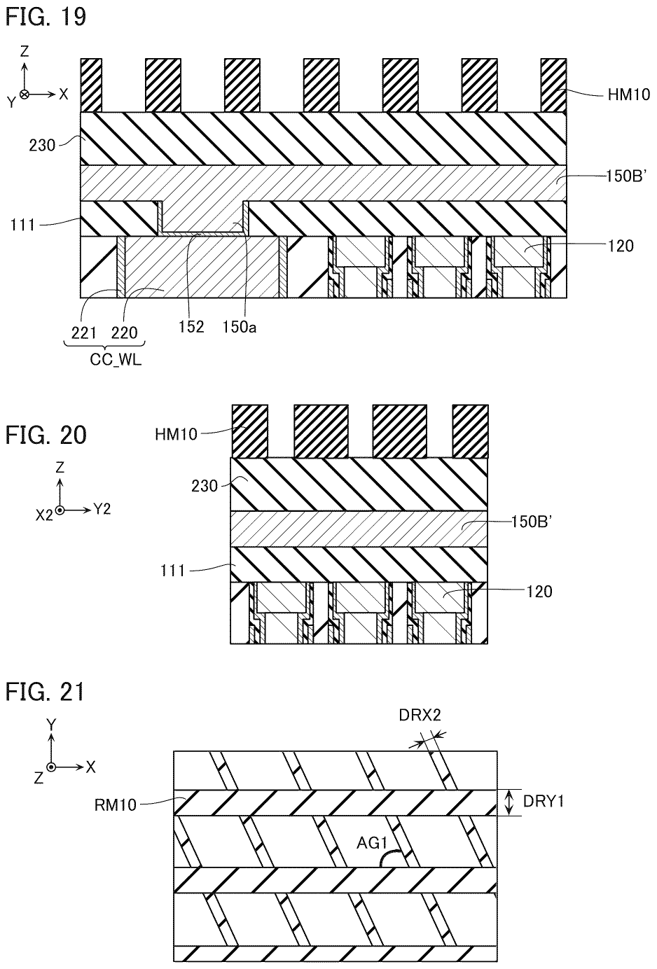

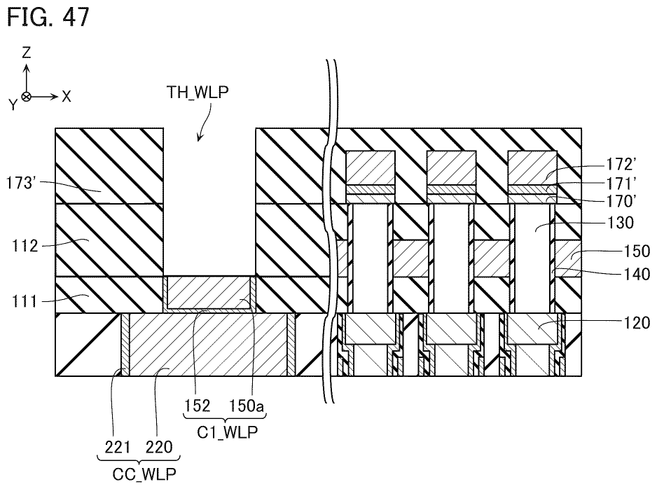

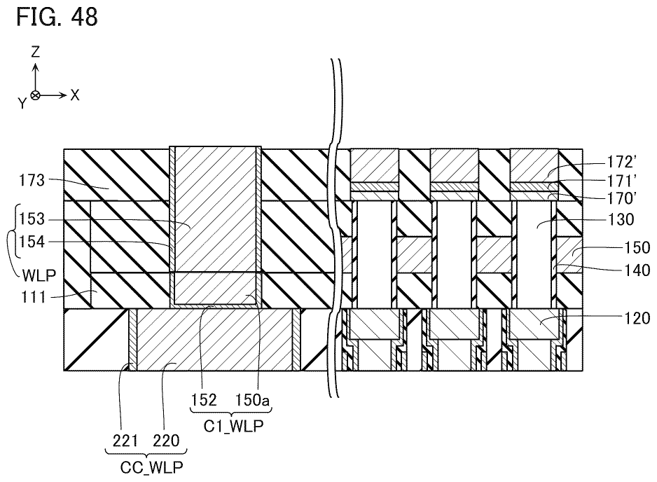

Note that FIGS. 14, 16, 19, 22, 25, 28, 30, 32, 35, 38, 41, 43, 45, 49, and 51 are schematic cross-sectional views of portions corresponding to FIG. 11. FIGS. 15, 17, 20, 23, 26, 29, 31, 33, 36, 39, 42, 44, 46, 50, and 52 are schematic cross-sectional views corresponding to a portion in which the configuration shown in FIG. 5 has been cut along the line E-E′ and viewed along a direction of the arrows. FIGS. 18, 24, 27, 34, 37, and 40 are plan views showing similar portions to in FIG. 5. FIG. 21 is a schematic plan view for explaining a method of forming the structure shown in FIGS. 19 and 20. FIGS. 47 and 48 are schematic cross-sectional views of portions corresponding to FIG. 12. Note that the drawings related to the manufacturing method are schematic, and that hereafter, for convenience of description, parts of configurations, and so on, thereof will sometimes be omitted.

In same manufacturing method, the peripheral circuit layer L_{PC} (FIG. 2), the plate line layer L_{PT} (FIG. 2), and the capacitor layer L_{CP} (FIG. 2) which includes the through electrodes CC_WL, CC_WLP and the conductive layer 120 (FIG. 14), are formed above the substrate Sub (FIG. 1). In addition, as shown in FIGS. 14 and 15, for example, the insulating layer 111 is formed on an upper surface of the capacitor layer L_{CP}. Moreover, an opening TH_150 is formed in a portion corresponding to the electrodes C1_WL, C1_WLP of the insulating layer 111, and the conductive layer 152 is formed inside the opening TH_150. This step is performed by the likes of CVD (Chemical Vapor Deposition) and RIE (Reactive Ion Etching), for example.

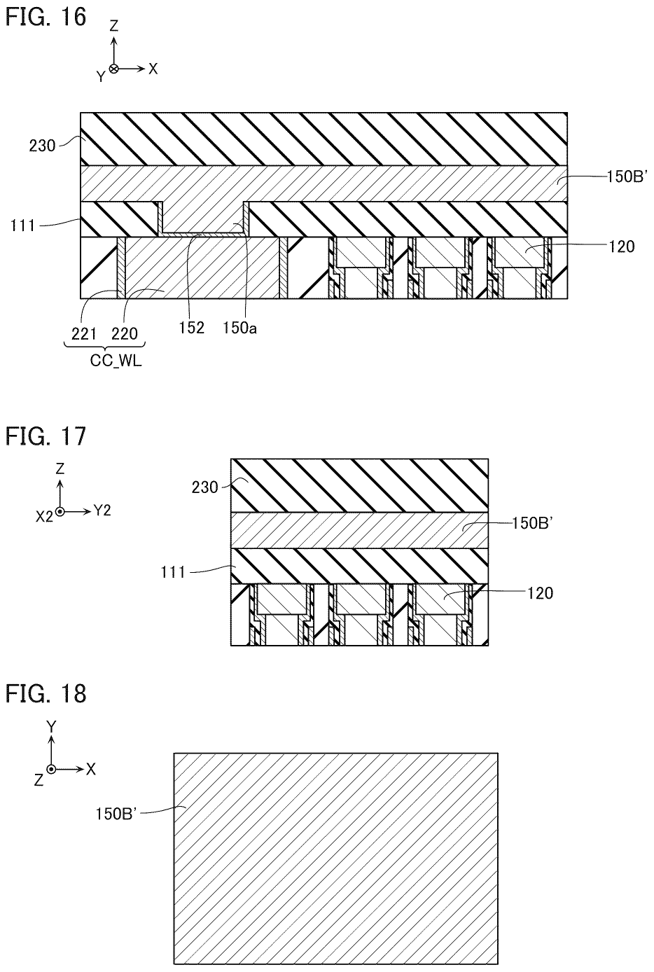

Next, as shown in FIGS. 16 to 18, for example, a conductive layer 150B′ and the conductive layer 150a that include a similar material to the conductive layer 150, are formed on an upper surface of the structure shown in FIGS. 14 and 15 and inside the opening TH_150. Moreover, an insulating layer 230 of the likes of silicon oxide (SiO₂) is formed on an upper surface of the conductive layer 150B′. This step is performed by the likes of CVD and RIE, for example.

Next, as shown in FIGS. 19 and 20, for example, a mask material HM10 is formed by photolithography, and so on, on an upper surface of the structure shown in FIGS. 16 and 17. The mask material HM10 may include an insulating layer of silicon nitride (SiN), silicon oxide (SiO₂), or the like, or a material such as a photoresist.

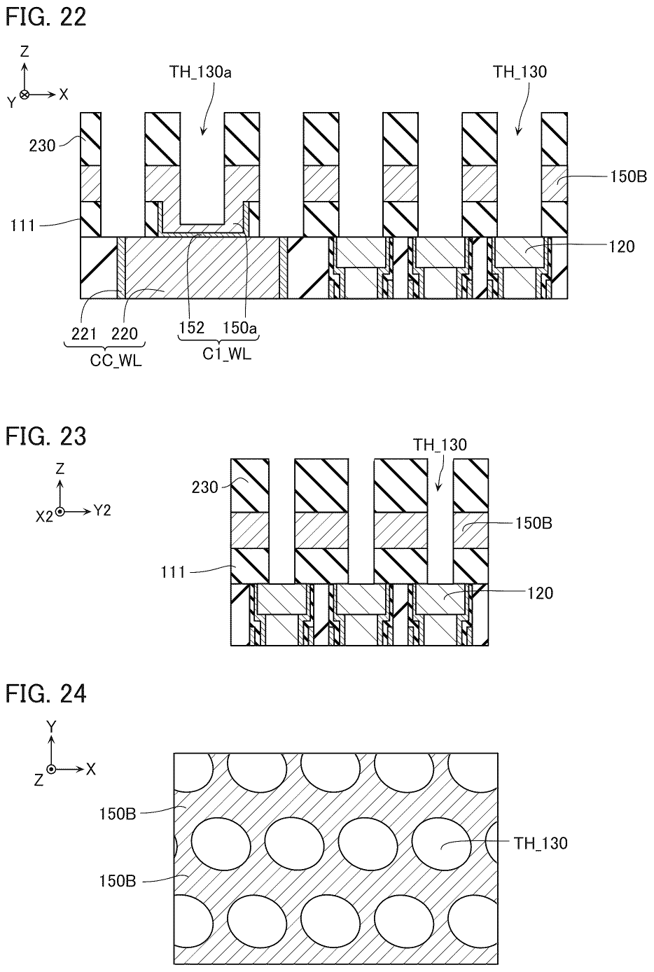

Note that FIG. 21 shows an example of a shape of a photoresist RM10 for forming the mask material HM10 by photolithography, and so on. The photoresist RM10 includes: a first portion extending in the X-direction and having a width DRY1 in the Y-direction; and a second portion which extends in a direction differing by an angle AG1 from an extending direction of the first portion, and has a width DRX2 in a direction orthogonal to its extending direction. Appropriate adjustment of the width DRY1, the width DRX2, and the angle AG1 enables shape, size, and arrangement interval of openings TH_130, TH_130a formed in a later-mentioned step shown in FIGS. 22 to 24, to be set to desired values.

Next, as shown in FIGS. 22 to 24, for example, the openings TH_130, TH_130a are formed. The opening TH_130 extends in the Z-direction and penetrates the insulating layer 230, the conductive layer 150B′, and the insulating layer 111 to expose the conductive layer 120. The opening TH_130a extends in the Z-direction and penetrates the insulating layer 230, the conductive layer 150B′, and the insulating layer 111 to expose the electrode C1_WL, and so on. This step results in a conductive layer 150B including a similar material to the conductive layer 150 being formed. This step is performed by the likes of RIE, for example.

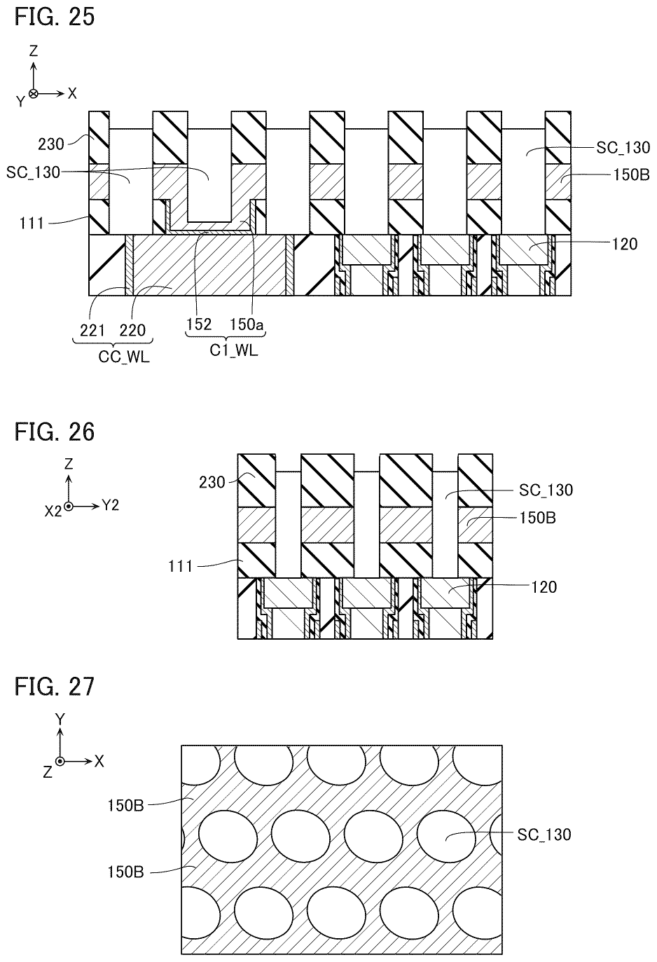

Next, as shown in FIGS. 25 to 27, for example, a sacrifice layer SC_130 of the likes of amorphous silicon (αSi) is formed inside the openings TH_130, TH_130a. This step is performed by the likes of CVD, for example.

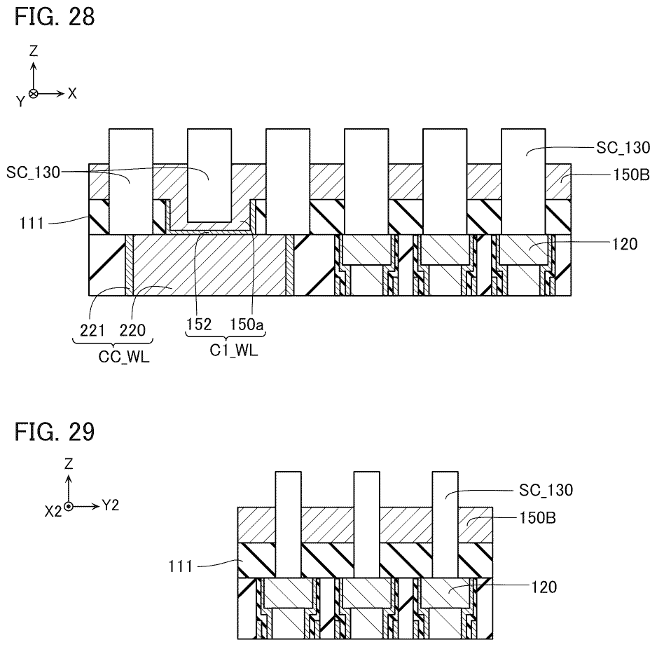

Next, as shown in FIGS. 28 and 29, for example, the insulating layer 230 is removed, and an upper surface of the conductive layer 150B and an upper end portion of the sacrifice layer SC_130 are exposed. This step is performed by the likes of wet etching, for example.

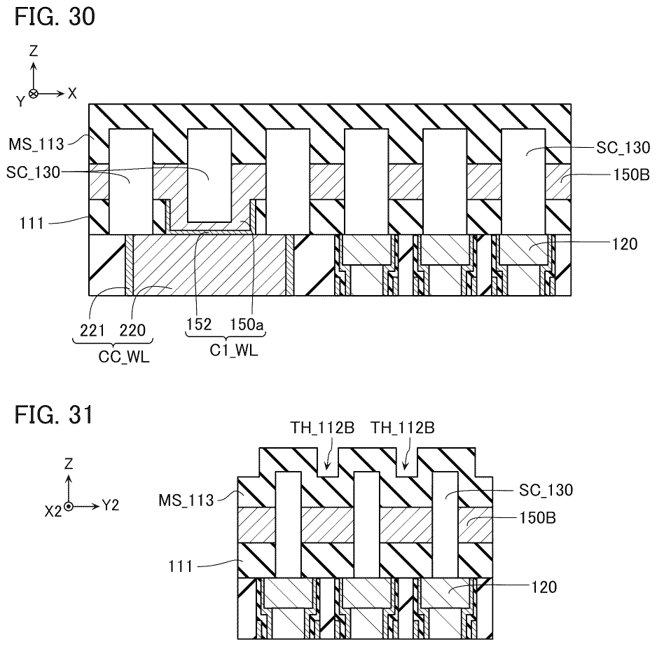

Next, as shown in FIGS. 30 and 31, for example, an insulating layer MS_113 of the likes of silicon oxide (SiO₂) is formed on an upper surface of the structure shown in FIGS. 28 and 29. This step results in spaces between the sacrifice layers SC_130 arranged in the X-direction being filled by the insulating layer MS_113 (FIG. 30). On the other hand, spaces between the sacrifice layers SC_130 arranged in the Y2 direction are not filled by the insulating layer MS_113, and the sacrifice layers SC_130 arranged in the Y2 direction have an opening TH_112B formed therebetween (FIG. 31). This step is performed by the likes of CVD and ALD (Atomic Layer Deposition), for example.

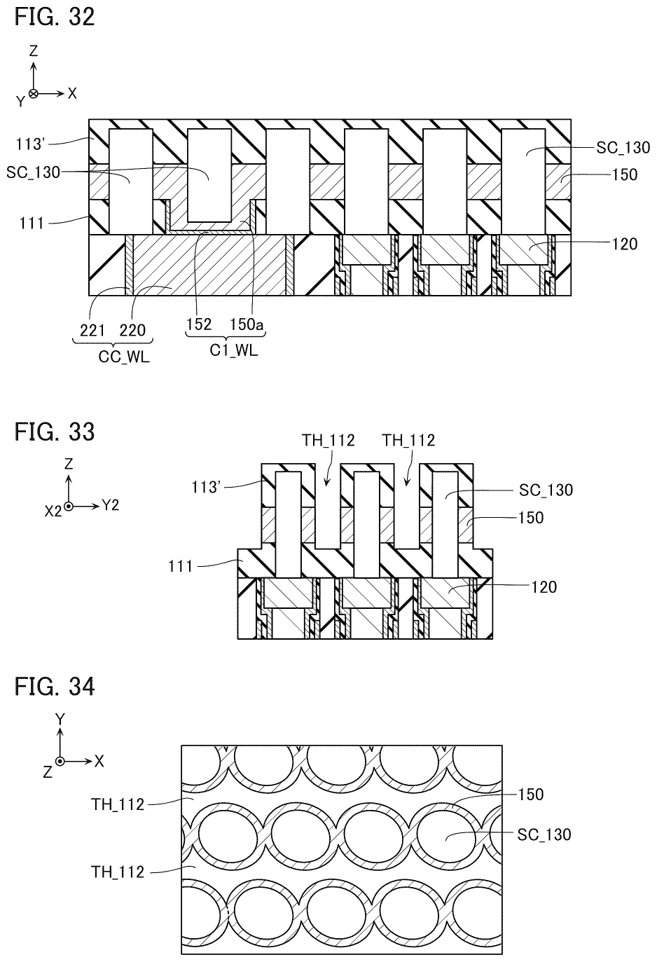

Next, as shown in FIGS. 32 to 34, for example, the insulating layer MS_113 is etched back to form an insulating layer 113′. In this step, a portion below where the opening TH_112B is formed, of the insulating layer MS_113 is removed, and furthermore, a part of the conductive layer 150B below the opening TH_112B is removed, so that in portions between the sacrifice layers SC_130 arranged in the Y2 direction, an opening TH_112 (FIG. 33) is formed. The opening TH_112 extends in the X-direction and the Z-direction, and penetrates the insulating layer 113′ and the conductive layer 150B to expose the insulating layer 111. This step results in the conductive layers 150 divided in the Y-direction being formed (FIG. 34). This step is performed by the likes of RIE, for example.

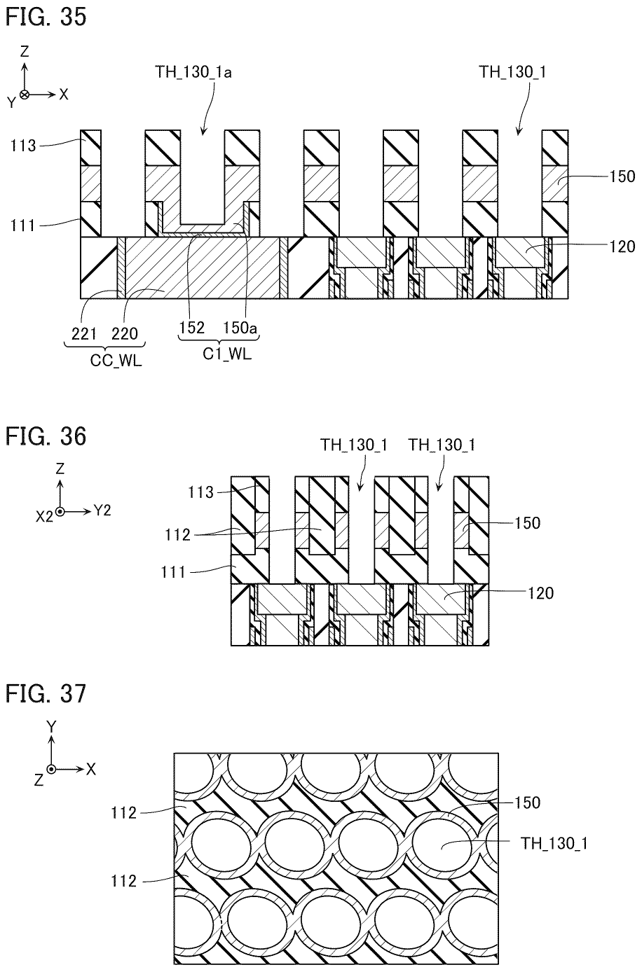

Next, as shown in FIGS. 36 and 37, for example, the insulating layer 112 is formed in the opening TH_112. This step is performed by the likes of CVD, for example. Moreover, as shown in FIGS. 35 to 37, for example, a portion of an upper surface of the insulating layer 113′, and the sacrifice layers SC_130 are removed, whereby openings TH_130_1, TH_130_1a are formed. This step is performed by the likes of CMP (Chemical Mechanical Planarization) and wet etching, for example.

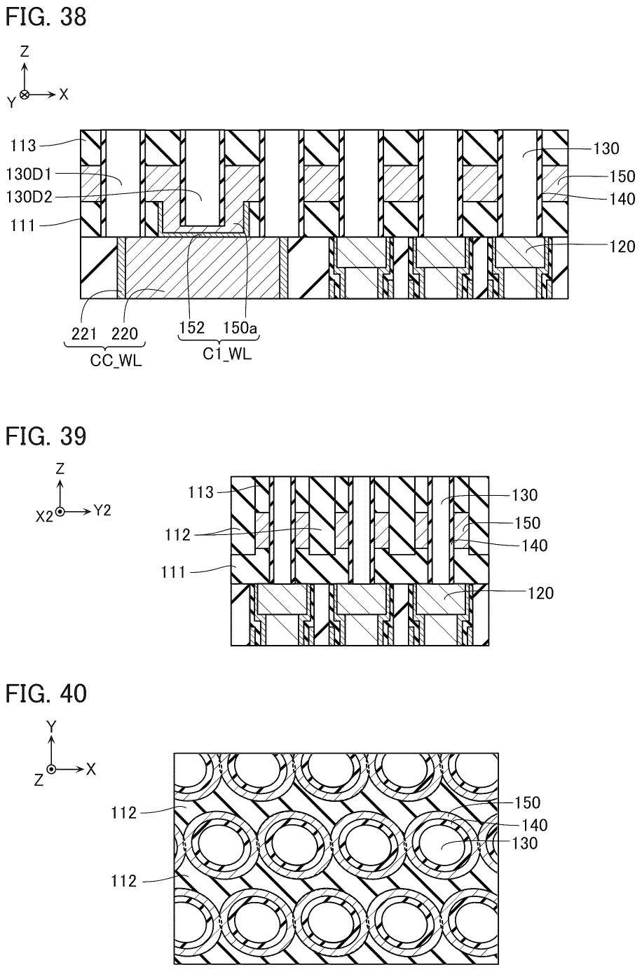

Next, as shown in FIGS. 38 to 40, for example, the insulating layer 140 is formed inside the openings TH_130_1, TH_130_1a, after which the semiconductor layer 130 is formed inside the openings TH_130_1, and the semiconductor layers 130D1, 130D2 are formed inside the opening TH_130_1a. In this step, the insulating layer 140 is formed by an insulating layer including a similar material to the insulating layer 140 being formed on inner side surfaces and bottom surfaces of the openings TH_130_1, TH_130_1a, after which portions formed on the bottom surfaces of the openings TH_130_1, TH_130_1a, of the insulating layer are removed. The semiconductor layers 130, 130D1, 130D2 are formed so as to contact inner side surfaces of the insulating layers 140 and fill in the openings TH_130_1, TH_130_1a. This step is performed by the likes of ALD, CVD, RIE, and CMP, for example.

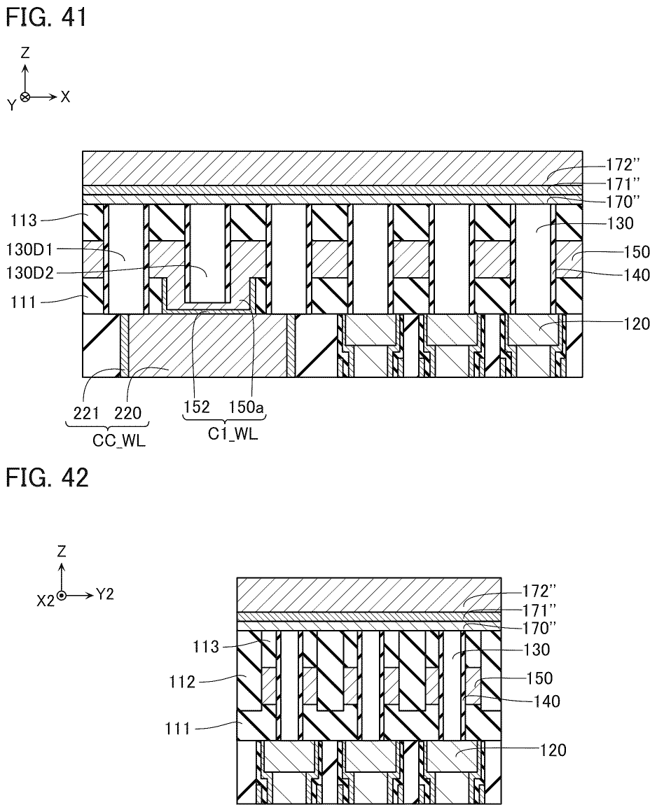

Next, as shown in FIGS. 41 and 42, for example, a conductive layer 170″, a conductive layer 171″, and a conductive layer 172″ are formed in order on an upper surface of the structure shown in FIGS. 38 and 39. The conductive layer 170″, the conductive layer 171″, and the conductive layer 172″ respectively include similar materials to the conductive layer 170, the conductive layer 171, and the conductive layer 172, for example. This step is performed by the likes of CVD, for example.

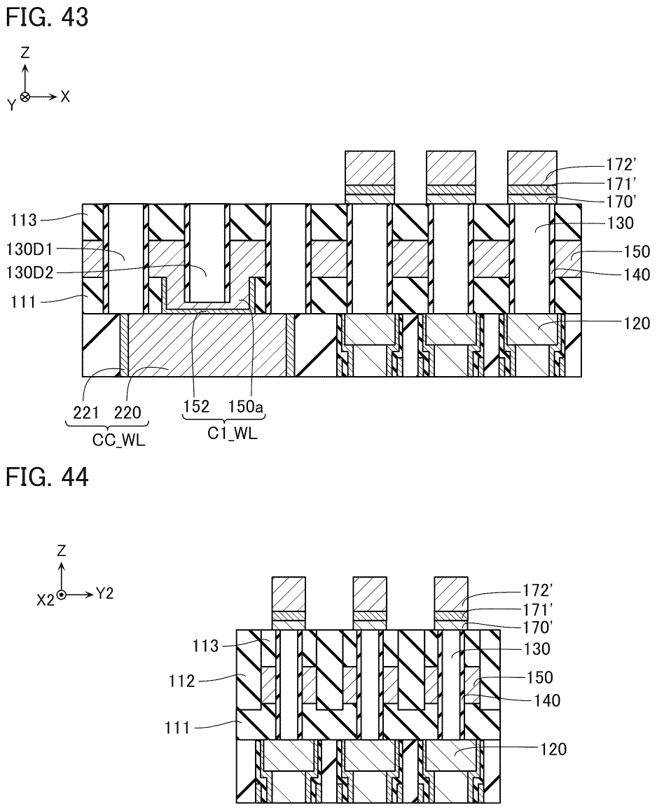

Next, as shown in FIGS. 43 and 44, for example, a mask material is formed by photolithography, and so on, at positions corresponding to the conductive layer 170, the conductive layer 171, and the conductive layer 172, and portions not covered by the mask material are removed, whereby a conductive layer 170′, a conductive layer 171′, and a conductive layer 172′ are formed. This step is performed by the likes of RIE, for example.

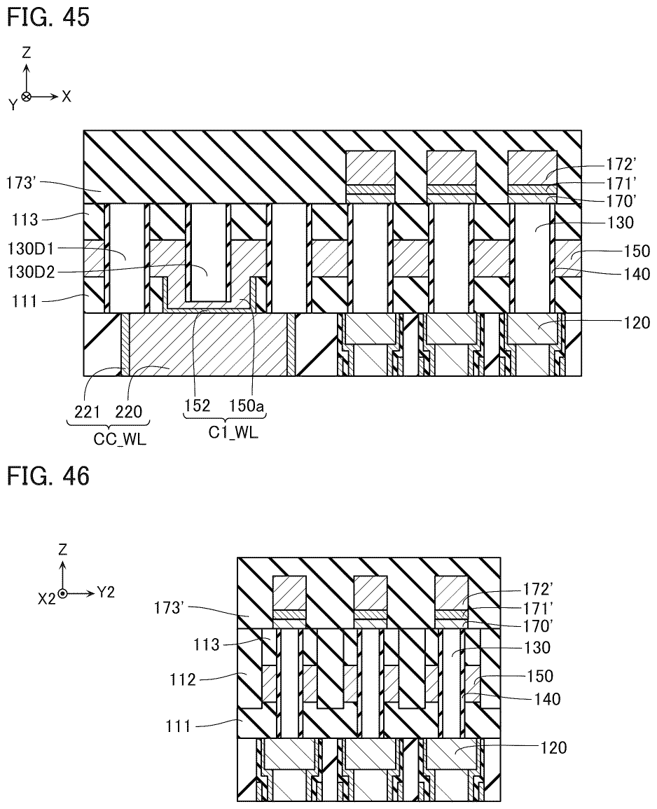

Next, as shown in FIGS. 45 and 46, for example, an insulating layer 173′ of the likes of silicon oxide (SiO₂) is formed on an upper surface of the structure shown in FIGS. 43 and 44. This step is performed by the likes of CVD, for example.

Next, as shown in FIG. 47, for example, an opening TH_WLP is formed at a position corresponding to the electrode WLP. The opening TH_WLP extends in the Z-direction and penetrates the insulating layer 173′ and the insulating layer 112 to expose the electrode C1_WLP. This step is performed by the likes of RIE, for example.

Next, as shown in FIG. 48, for example, similar materials to the conductive layer 154 and the conductive layer 153 are formed in order inside the opening TH_WLP, moreover, an upper surface of the structure shown in FIG. 48 is planarized until the conductive layer 172′ is exposed, this resulting in the conductive layer 154, the conductive layer 153, and the insulating layer 173 being formed. This step is performed by the likes of CVD and CMP, for example.

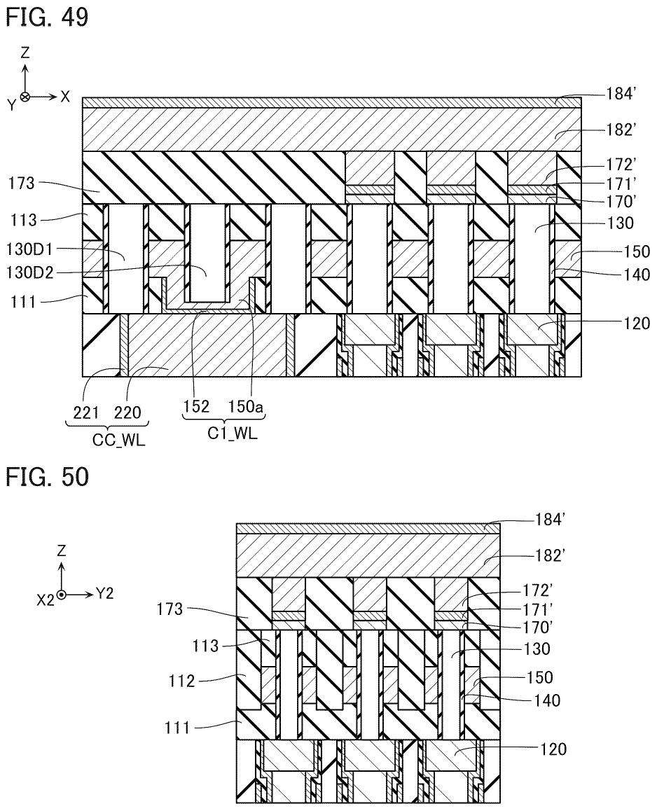

Next, as shown in FIGS. 49 and 50, for example, a conductive layer 182′ and a conductive layer 184′ are formed on upper surfaces of the insulating layer 173 and the conductive layer 172′. This step is performed by the likes of CVD, for example.

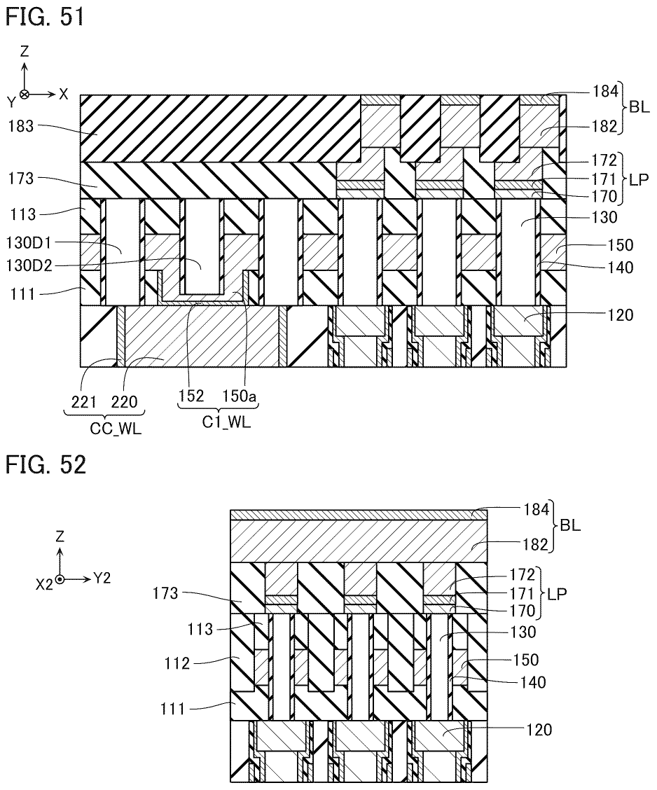

Next, as shown in FIGS. 51 and 52, for example, the conductive layer 182, the conductive layer 184, and the insulating layer 183 are formed. This step is performed by a mask material being formed by photolithography, and so on, at a position corresponding to the conductive layer 182 and the conductive layer 184, and portions not covered by the mask material being removed, for example. This step results in parts of the conductive layer 170′, the conductive layer 171′, and the conductive layer 172′ being simultaneously removed, and the conductive layer 170, the conductive layer 171, and the conductive layer 172 being formed. This step is performed by the likes of RIE, for example.

Next, the wiring layer L_{UL} (FIG. 2), and so on, are formed on an upper surface of the structure shown in FIGS. 51 and 52, whereby the semiconductor device according to the first embodiment is manufactured.

### [Advantages]

In the semiconductor device according to the present embodiment, as shown in FIG. 5, a width DT10 which is the closest distance between fellow outer peripheral surfaces of two semiconductor layers 130 arranged in the Y2 direction is greater than a width DX10 which is the closest distance between fellow outer peripheral surfaces of two semiconductor layers 130 arranged in the X-direction.

In such a structure, in the step described with reference to FIGS. 30 to 34, the spaces between the sacrifice layers SC_130 arranged in the Y2 direction, that correspond to the positions where the semiconductor layers 130 are to be formed, will not be filled by the insulating layer MS_113 (FIG. 31). As a result, the conductive layers 150 formed by etching back the insulating layer MS_113 (FIGS. 32 to 34) will be connected in the X-direction, but divided in the Y-direction. In such a step, the conductive layer 150 can be formed in a self-arranging manner along the sacrifice layers SC_130 arranged in the X-direction.

In the semiconductor device according to the present embodiment, the conductive layer 150 functioning as the word line WL is enabled to be highly precisely arranged to formation positions of the semiconductor layers 130 and can be precisely processed, even when the semiconductor layers 130 functioning as the channel region of the select transistor ST (FIG. 1) are configured with more minute shapes and more highly dense arrangements. This enables manufacturing of a select transistor ST (FIG. 1) having excellent transistor characteristics, and of a minute word line WL, that have high levels of integration. Moreover, costs during manufacturing can be reduced due to there being no need for a fine photolithography step for processing the conductive layer 150.

### [Modified Example 1 of First Embodiment]

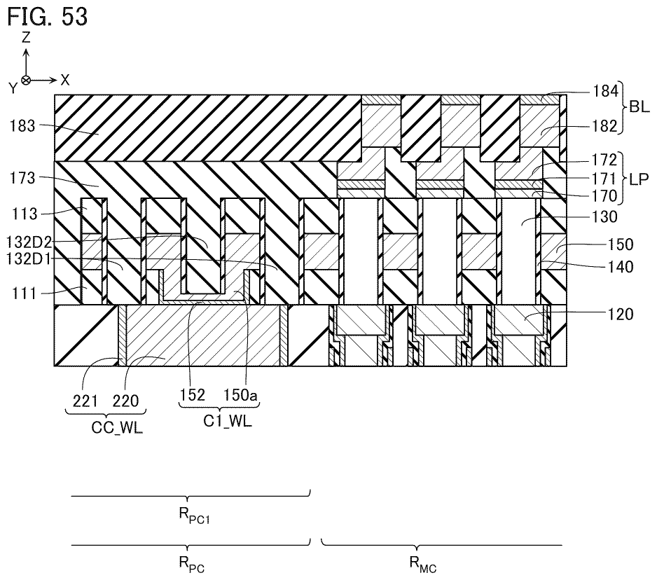

Next, modified example 1 of the semiconductor device according to the first embodiment will be described with reference to FIGS. 53 and 54. FIGS. 53 and 54 are respectively a schematic cross-sectional view and plan view showing a configuration of a part of the semiconductor device according to the present modified example. Note that FIG. 53 shows a portion corresponding to FIG. 11. FIG. 54 shows a structure of the end portion of the conductive layer 150.

The semiconductor device according to the present modified example (FIG. 53) is provided with insulating layers 132D1, 132D2 instead of the semiconductor layers 130D1, 130D2 (FIG. 11).

The insulating layers 132D1, 132D2 extend in the Z-direction and have substantially circular column-like shapes, for example. Parts of the insulating layers 132D1, 132D2 face the conductive layer 150. The insulating layers 132D1, 132D2 include the likes of silicon oxide (SiO₂), for example, similar to in the insulating layer 173. The insulating layers 132D1, 132D2 may be provided continuously with the insulating layer 173.

Moreover, in the present modified example, the electrode C1_WL is provided so as to surround a part of a side surface of the insulating layer 132D2, and a lower surface of the insulating layer 132D2.

FIG. 54 shows: the insulating layer 132D1 provided furthest to the end in the X-direction; and the end portion in the X-direction of the conductive layer 150. In the XY cross section shown in FIG. 54, for example, the conductive layer 150 is provided separated by the width DW11 from an outer peripheral surface of the insulating layer 132D1, and includes a ring-like portion PT13 surrounding the insulating layer 132D1. The portion PT13 is at least a part of the end portion in the X-direction of the conductive layer 150. Moreover, a part of an outer peripheral surface of the portion PT13 contacts the insulating layer 112.

### [Manufacturing Method of Modified Example 1 of First Embodiment]

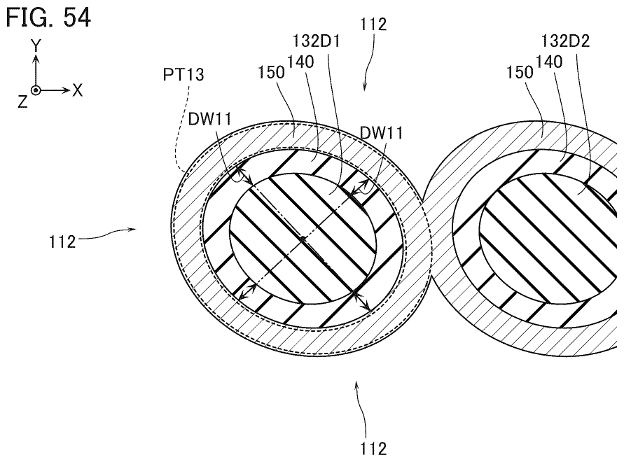

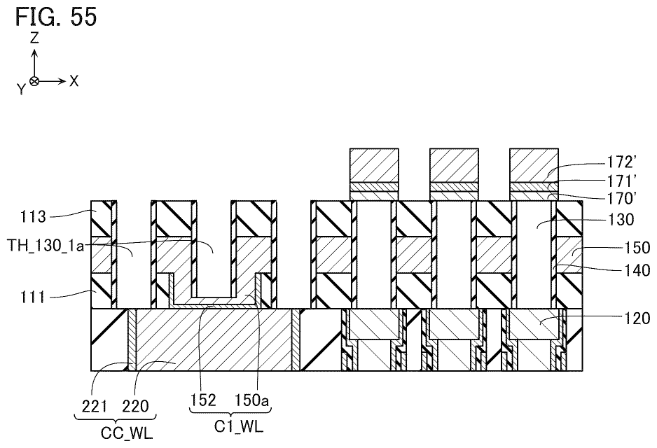

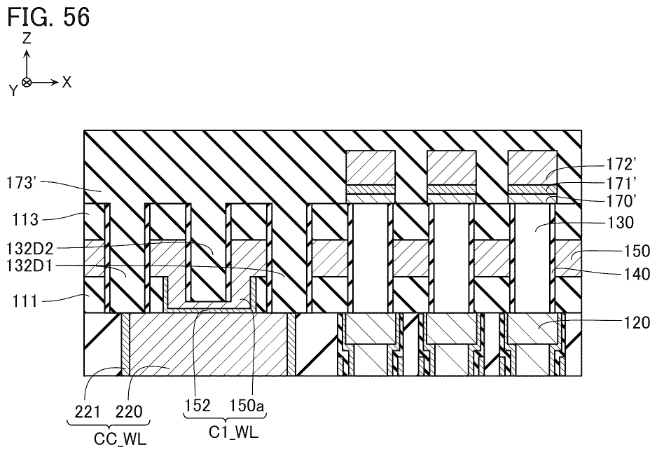

Next, a manufacturing method of the semiconductor device according to the present modified example will be described with reference to FIGS. 55 and 56. FIGS. 55 and 56 are schematic cross-sectional views for explaining the manufacturing method of the semiconductor device according to modified example 1 of the first embodiment. Note that FIGS. 55 and 56 are schematic cross-sectional views of portions corresponding to FIG. 53.

In manufacturing of the semiconductor device according to the present modified example, similar steps to in the manufacturing method of the first embodiment are performed up to the steps described with reference to FIGS. 14 to 44.

Next, as shown in FIG. 55, for example, the semiconductor layers 130D1, 130D2 are removed to form the openings TH_130_1a. This step is performed by the likes of wet etching, for example.

Next, as shown in FIG. 56, for example, an insulating layer of the likes of silicon oxide (SiO₂) is formed on an upper surface of the structure shown in FIG. 55, whereby the insulating layers 132D1, 132D2 inside the openings TH_130_1a, and the insulating layer 173′ are formed. This step is performed by the likes of CVD, for example.

Next, the steps described with reference to FIG. 47 onward, for example, are performed similarly to in the manufacturing method of the first embodiment.

### [Modified Example 2 of First Embodiment]

Next, modified example 2 of the semiconductor device according to the first embodiment will be described with reference to FIGS. 57 to 59. FIGS. 57 to 59 are respectively a schematic plan view, perspective view, and cross-sectional view showing a configuration of a part of the semiconductor device according to the present modified example. Note that FIGS. 57, 58, and 59 respectively show portions corresponding to FIGS. 9, 10, and 12.

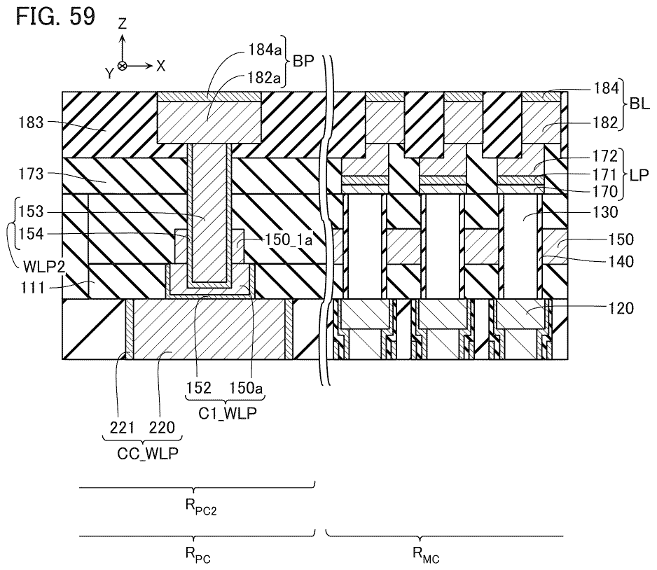

The transistor layer L_{Tr} of the region R_{PC2} in the present modified example (FIG. 59) is not provided with the electrode WLP (FIG. 12), but instead, is provided with an electrode WLP2 and a conductive layer 150_1a (FIG. 59).

As shown in FIG. 59, for example, the electrode WLP2 has an upper end connected to the conductive layer BP, and has a lower end electrically connected to the electrode C1_WLP. A part of a side surface, and a lower surface of the electrode WLP2 may be surrounded by the electrode C1_WLP. The electrode WLP2 includes the conductive layer 153 and the conductive layer 154 similar to in the electrode WLP (FIG. 12).

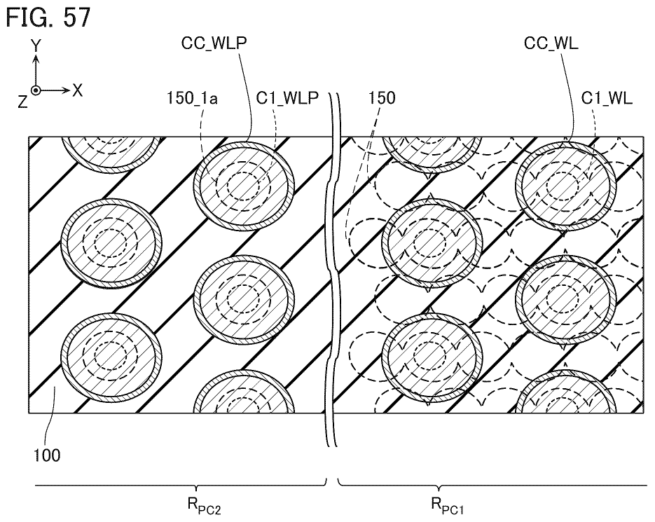

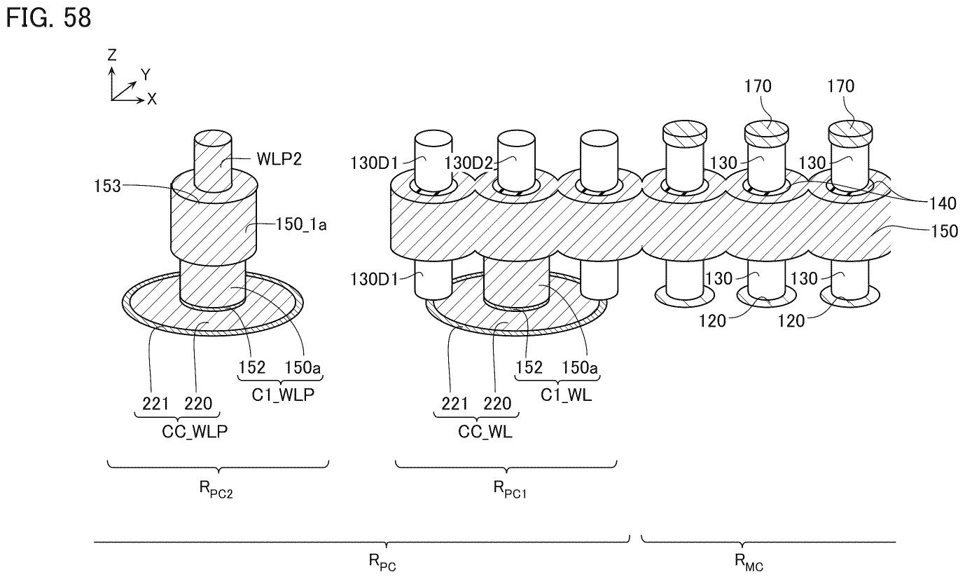

As shown in FIGS. 58 and 59, for example, the conductive layer 150_1a is provided in the same layer as the conductive layer 150. The conductive layer 150_1a may include a similar material to the conductive layer 150, and may be formed by similar steps to the conductive layer 150. As shown in FIGS. 58 and 59, for example, the conductive layer 150_1a may be provided so as to surround a part of the electrode WLP2.

Formation of the conductive layer 150_1a may be performed as follows, for example. In a step corresponding to FIGS. 22 to 24, for example, an opening similar to the opening TH_130a is formed on the electrode C1_WLP, too. Moreover, in a step corresponding to FIGS. 25 to 29, a sacrifice layer similar to the sacrifice layer SC_130 is formed on the electrode C1_WLP, too. Hence, in a step corresponding to FIGS. 30 to 34, the conductive layer 150_1a including a similar material to the conductive layer 150 will be formed on the electrode C1_WLP, too.

### [Modified Example 3 of First Embodiment]

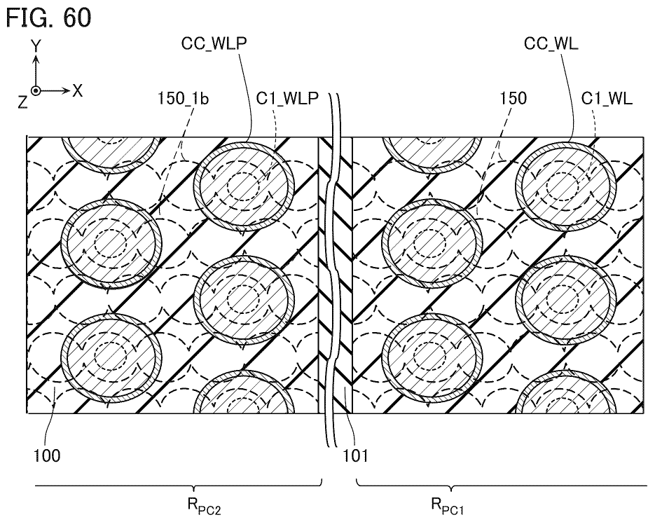

Next, modified example 3 of the semiconductor device according to the first embodiment will be described with reference to FIGS. 60 to 62. FIGS. 60 to 62 are respectively a schematic plan view, perspective view, and cross-sectional view showing a configuration of a part of the semiconductor device according to the present modified example. Note that FIGS. 60, 61, and 62 respectively show portions corresponding to FIGS. 9, 10, and 12.

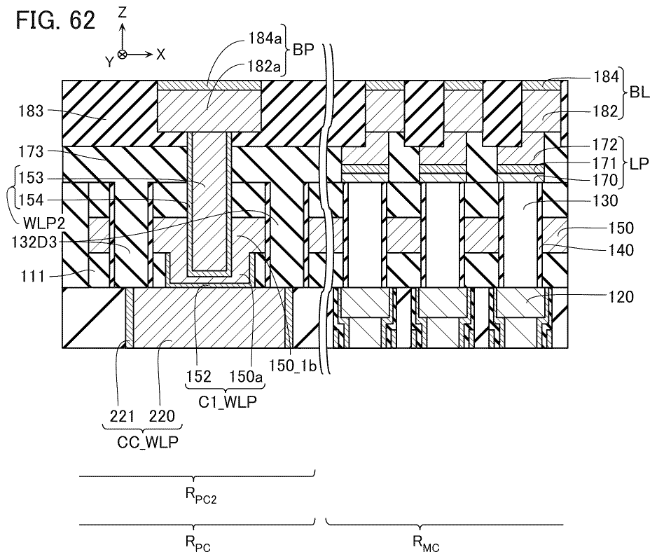

The transistor layer L_{Tr} of the region R_{PC2} in the present modified example (FIG. 62) is not provided with the electrode WLP (FIG. 12), but instead, is provided with the electrode WLP2 similar to in modified example 2 (FIG. 59), and is further provided with an insulating layer 132D3 and a conductive layer 150_1b (FIG. 62). Moreover, in the present modified example, as shown in FIG. 60, an insulating layer 101 of the likes of silicon oxide (SiO₂) may be provided between the region R_{PC1} and the region R_{PC2}.

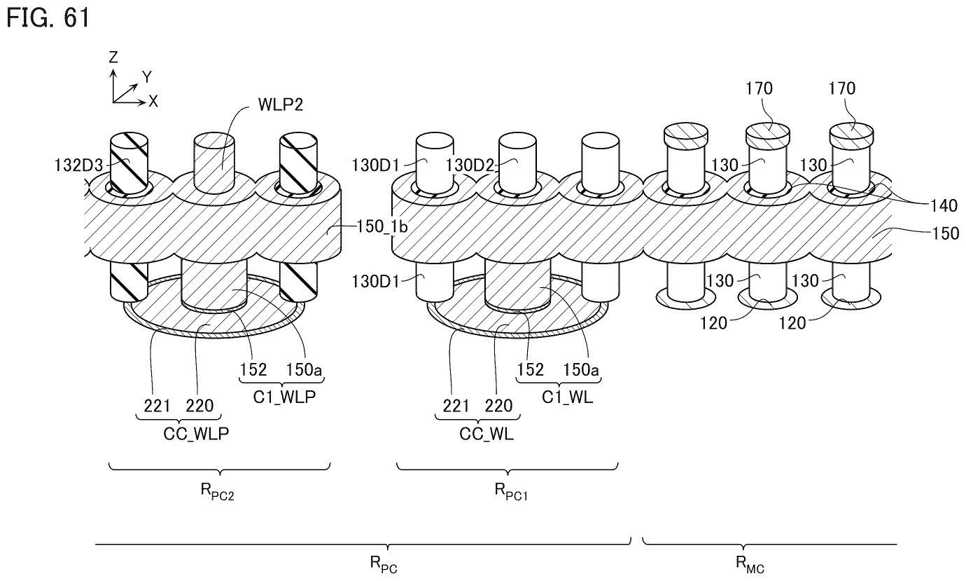

As shown in FIGS. 61 and 62, for example, the conductive layer 150_1b is provided in the same layer as the conductive layer 150. The conductive layer 150_1b includes a similar material to the conductive layer 150, and is formed by similar steps to the conductive layer 150. As shown in FIGS. 61 and 62, for example, the conductive layer 150_1b may be provided so as to surround parts of the electrode WLP2 and the insulating layer 132D3.

As shown in FIG. 60, for example, the insulating layer 101 may be provided so as to divide the conductive layers 150 of the region R_{PC1} and the conductive layers 150_1b of the region R_{PC2}.

The insulating layer 132D3 (FIG. 62) extends in the Z-direction and has a substantially circular column-like shape, for example. A part of the insulating layer 132D3 faces the conductive layer 150_1b. The insulating layer 132D3 includes the likes of silicon oxide (SiO₂), for example, similar to in the insulating layer 173. The insulating layer 132D3 may be provided continuously with the insulating layer 173.

Formation of the conductive layer 150_1b may be performed as follows, for example. In a step corresponding to FIGS. 22 to 24, for example, a plurality of openings similar to the opening TH_130a are formed in the region R_{PC2}, too. Moreover, in a step corresponding to FIGS. 25 to 29, a plurality of sacrifice layers similar to the sacrifice layer SC_130 are formed in the region R_{PC2}, too. Hence, in a step corresponding to FIGS. 30 to 34, the conductive layer 150_1b including a similar material to the conductive layer 150 will be formed in the region R_{PC2}, too.

Note that in the example of the XY cross section shown in FIG. 60, the conductive layer 150_1b of the region R_{PC2} has a ranging shape of its ring-like portions, similarly to the conductive layer 150 of the region R_{PC1}. However, a shape of the conductive layer 150_1b is appropriately adjustable. For example, the conductive layer 150_1b may have a ranging shape of ring-like portions that are elliptical, racetrack-shaped, and so on, with minor axes and major axes longer than in the conductive layer 150. Moreover, even when the conductive layer 150_1b has a similar shape to the conductive layer 150 at its center portion in the X-direction, it may have a different shape from the conductive layer 150, such as an elliptical shape or racetrack shape with longer major axis than in the conductive layer 150, at its end portion in the X-direction.

### Second Embodiment

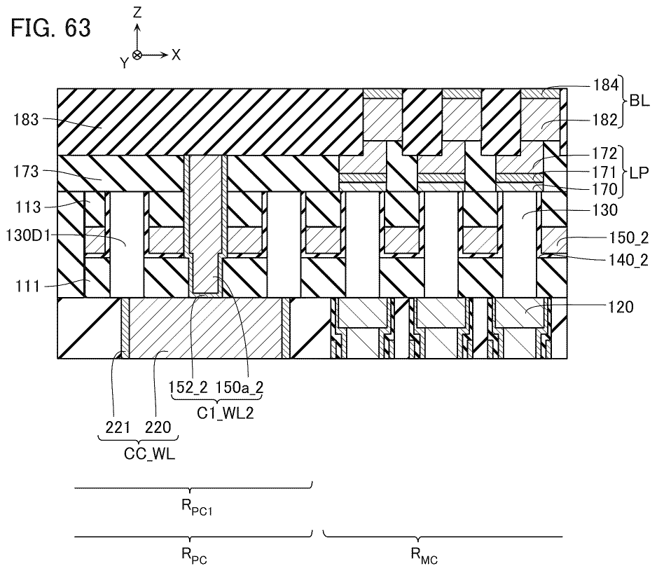

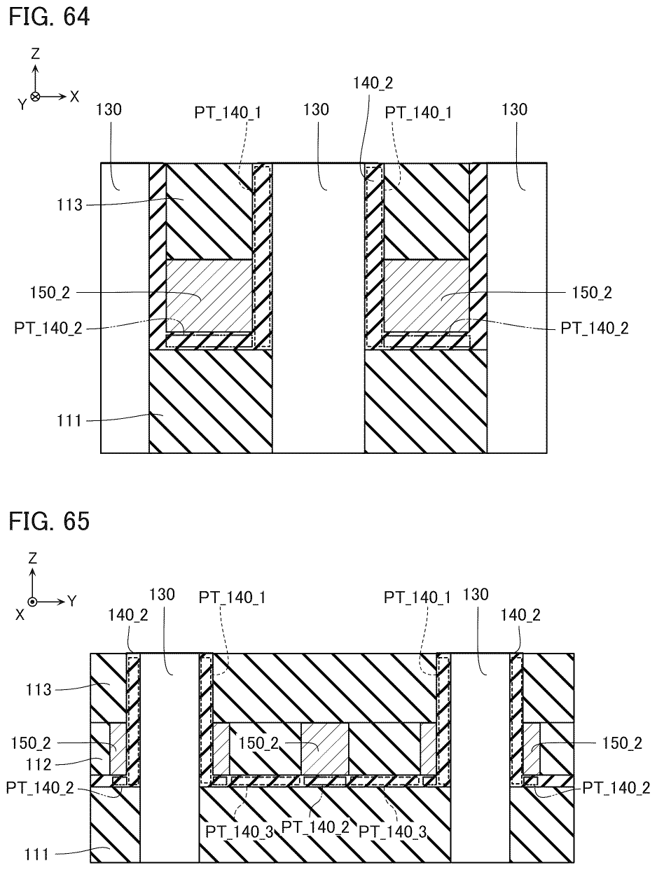

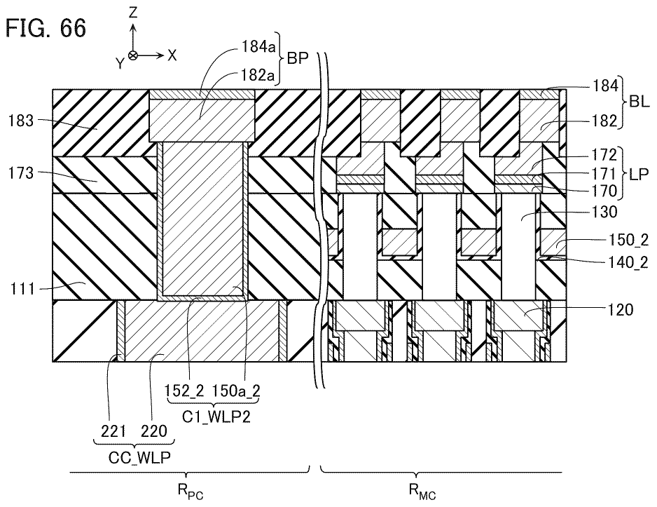

Next, a semiconductor device according to a second embodiment will be described using FIGS. 63 to 66. FIGS. 63 to 66 are schematic cross-sectional views showing a configuration of a part of the semiconductor device according to the second embodiment. Note that FIGS. 63 and 66 show portions corresponding to FIGS. 11 and 12. FIG. 64 is a schematic cross-sectional view in which a part of the configuration shown in FIG. 63 has been enlarged. FIG. 65 is a schematic cross-sectional view in which the configuration shown in FIG. 5 has been cut along the line F-F′ and viewed along a direction of the arrows.

The semiconductor device according to the present embodiment is basically configured similarly to the semiconductor device according to the first embodiment (FIGS. 11 and 12). However, the semiconductor device according to the present embodiment (FIG. 63) comprises an insulating layer 140_2 (FIG. 63) instead of the insulating layer 140 (FIG. 11), a conductive layer 150_2 (FIG. 63) instead of the conductive layer 150 (FIG. 11), an electrode C1_WL2 (FIG. 63) instead of the electrode C1_WL and semiconductor layer 130D2 (FIG. 11), and an electrode C1_WLP2 (FIG. 66) instead of the electrode C1_WLP and the electrode WLP (FIG. 12).

The insulating layer 140_2 (FIG. 63) is basically provided similarly to the insulating layer 140 (FIG. 11). However, the insulating layer 140_2 (FIG. 63), unlike the insulating layer 140 (FIG. 11), is not provided between the insulating layer 111 and the semiconductor layer 130. Moreover, as shown in FIGS. 64 and 65, the insulating layer 140_2 is also provided continuously on a lower surface of the conductive layer 150_2 (FIG. 64) and a part of a lower surface of the insulating layer 112 (FIG. 65).

In the XZ cross section shown in FIG. 64, for example, the insulating layer 140_2 includes: a portion PT_140_1 provided between the insulating layer 113 and the conductive layer 150_2, and the semiconductor layer 130; and a portion PT_140_2 provided on a lower surface (a surface on the substrate side) of the conductive layer 150_2. The portion PT_140_1 and the portion PT_140_2 are provided continuously.

In the YZ cross section shown in FIG. 65, for example, the insulating layer 140_2 includes: the portion PT_140_1; the portion PT_140_2; and a portion PT_140_3 provided between the portion PT_140_1 and the portion PT_140_2. The portion PT_140_3 is provided on a part of the lower surface (the surface on the substrate side) of the insulating layer 112. The portion PT_140_1, the portion PT_140_2, and the portion PT_140_3 are provided continuously.

The conductive layer 150_2 (FIG. 63) is basically provided similarly to the conductive layer 150 (FIG. 11). However, a lower surface of the conductive layer 150_2 contacts the insulating layer 140_2.

The electrode C1_WL2 (FIG. 63) has a lower surface connected to the through electrode CC_WL. The electrode C1_WL2 includes a conductive layer 150a_2 of the likes of tungsten (W), and a conductive layer 152_2 of the likes of titanium nitride (TiN). The conductive layer 150_2 and the through electrode CC_WL are electrically connected via the electrode C1_WL2.

The electrode C1_WLP2 (FIG. 66) has an upper end connected to the conductive layer BP, and has a lower end electrically connected to the through electrode CC_WLP, for example. The electrode C1_WLP2 includes the conductive layer 150a_2 and the conductive layer 152_2.

### [Manufacturing Method 1 of Second Embodiment]

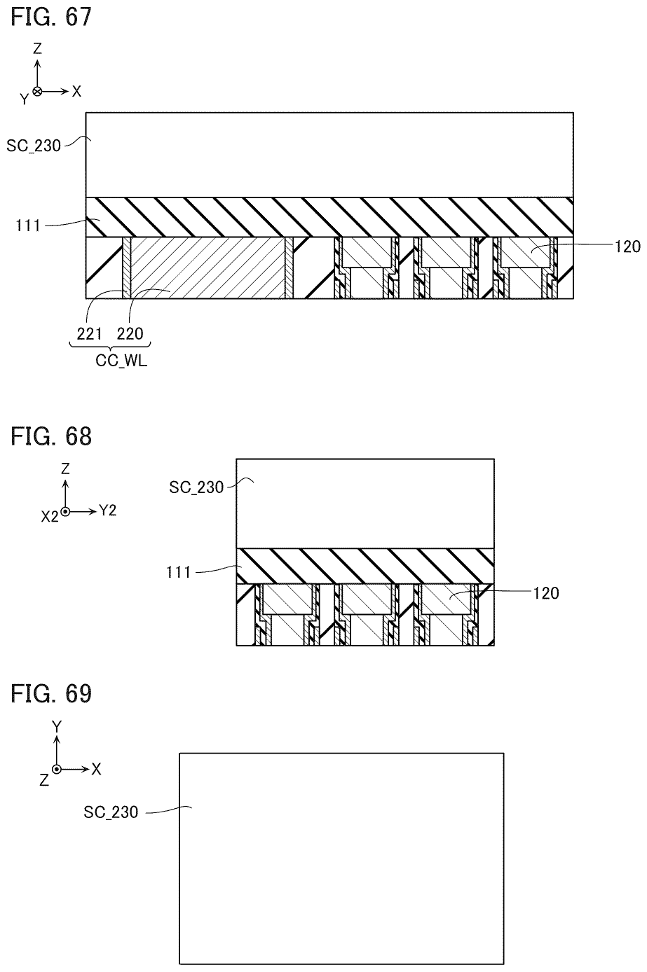

Next, a manufacturing method 1 of the semiconductor device according to the present embodiment will be described with reference to FIGS. 67 to 91. FIGS. 67 to 91 are schematic cross-sectional views and plan views for explaining the manufacturing method 1 of the semiconductor device according to the second embodiment.

Note that FIGS. 67, 70, 73, 76, 79, 82, 85, 88, and 91 are schematic cross-sectional views of portions corresponding to FIG. 63. FIGS. 68, 71, 74, 77, 80, 83, 86, and 89 are schematic cross-sectional views corresponding to a portion in which the configuration shown in FIG. 5 has been cut along the line E-E′ and viewed along a direction of the arrows. FIGS. 69, 72, 75, 78, 81, 84, 87, and 90 are plan views showing similar portions to in FIG. 5. Note that the drawings related to the manufacturing method are schematic, and that hereafter, for convenience of description, parts of configurations, and so on, thereof will sometimes be omitted.

In same manufacturing method, the peripheral circuit layer L_{PC} (FIG. 2), the plate line layer L_{PT} (FIG. 2), and the capacitor layer L_{CP} (FIG. 2) which includes the through electrodes CC_WL, CC_WLP and the conductive layer 120 (FIG. 14), are formed above the substrate Sub (FIG. 1), similarly to in the first embodiment. In addition, as shown in FIGS. 67 to 69, for example, the insulating layer 111 and a sacrifice layer SC_230 of the likes of amorphous silicon (αSi) are formed on the upper surface of the capacitor layer L_{CP}. This step is performed by the likes of CVD, for example.

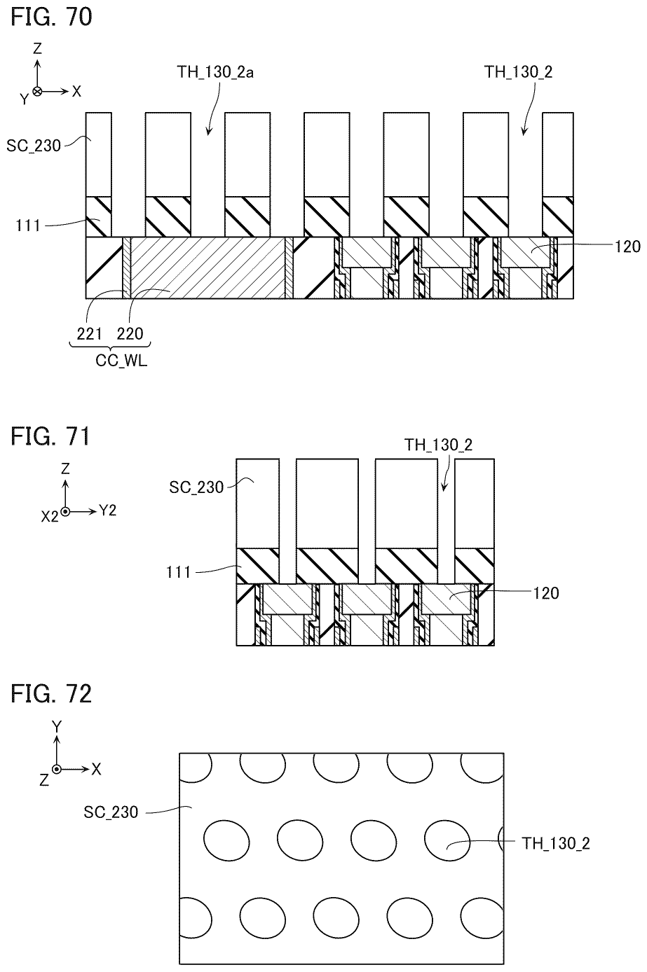

Next, as shown in FIGS. 70 to 72, for example, openings TH_130_2, TH_130_2a are formed. The opening TH_130_2 extends in the Z-direction and penetrates the sacrifice layer SC_230 and the insulating layer 111 to expose the conductive layer 120. The opening TH_130_2a extends in the Z-direction and penetrates the sacrifice layer SC_230 and the insulating layer 111 to expose the through electrode CC_WL, and so on. This step is performed by the likes of RIE, for example.

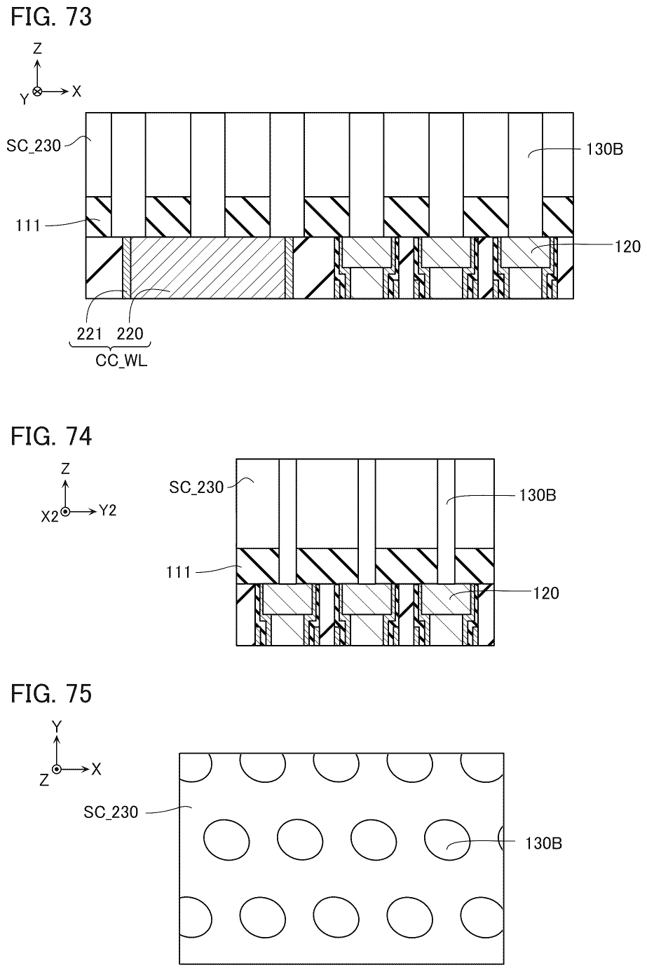

Next, as shown in FIGS. 73 to 75, for example, a semiconductor layer 130B including a similar material to the semiconductor layer 130 is formed inside the openings TH_130_2, TH_130_2a. This step is performed by the likes of CVD and CMP, for example.

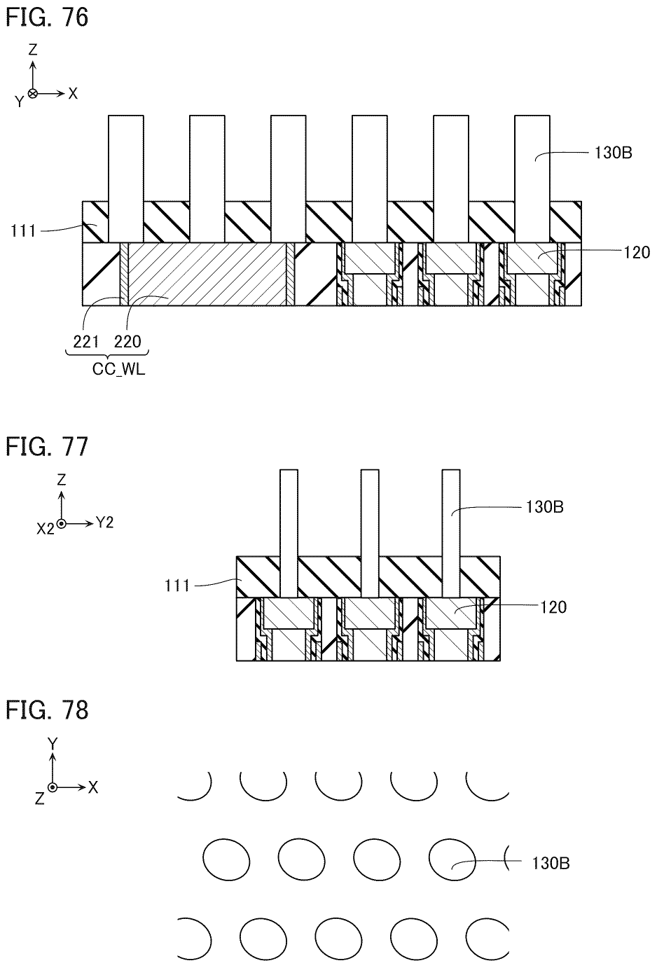

Next, as shown in FIGS. 76 to 78, for example, the sacrifice layer SC_230 is removed, and the upper surface of the insulating layer 111 and an upper surface and a part of an outer peripheral surface of the semiconductor layer 130B are exposed. This step is performed by the likes of wet etching, for example.

Next, as shown in FIGS. 79 to 81, for example, an insulating layer 140_2B including a similar material to the insulating layer 140_2 is formed on the upper surface and the part of the outer peripheral surface of the semiconductor layer 130B, and on the upper surface of the insulating layer 111. This step is performed by the likes of CVD and ALD, for example.

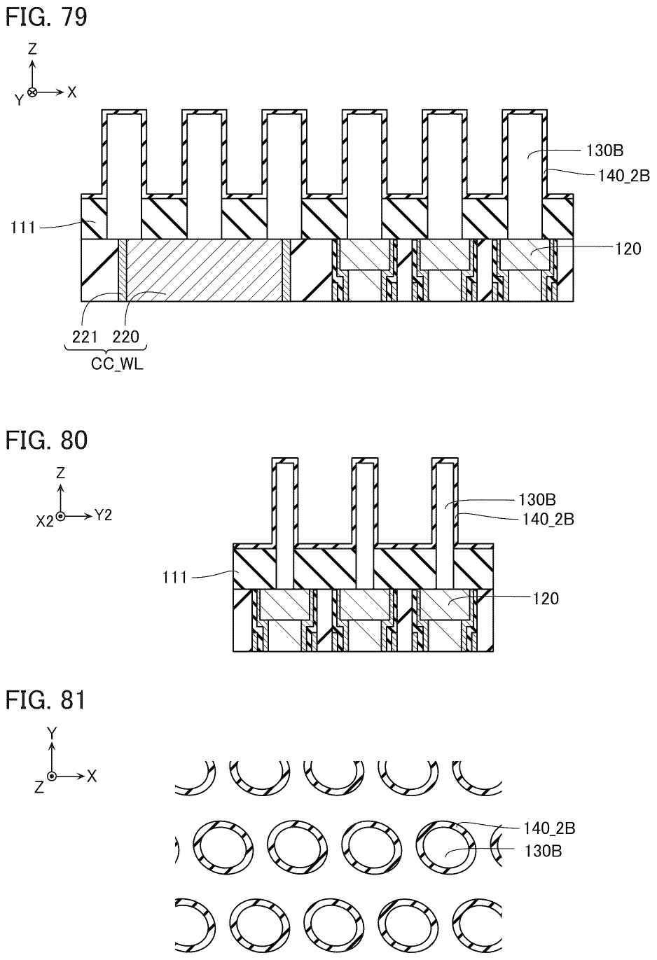

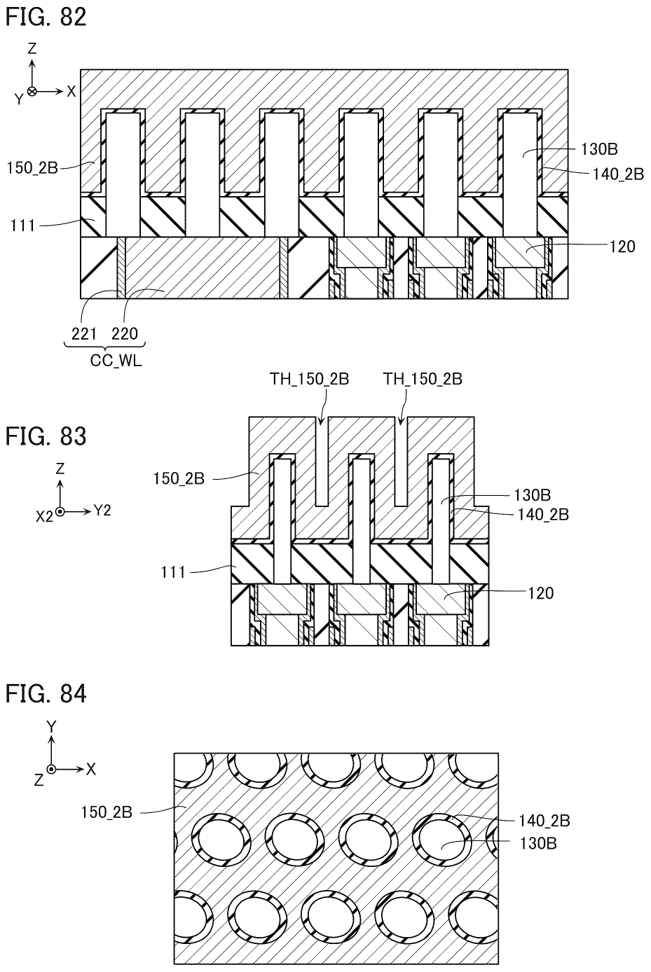

Next, as shown in FIGS. 82 to 84, for example, a conductive layer 150_2B including a similar material to the conductive layer 150_2 is formed on an upper surface of the structure shown in FIGS. 79 and 80. This step results in spaces between the semiconductor layers 130B arranged in the X-direction being filled by the conductive layer 150_2B (FIG. 82). On the other hand, spaces between the semiconductor layers 130B arranged in the Y2 direction are not filled by the conductive layer 150_2B, and the semiconductor layers 130B arranged in the Y2 direction have an opening TH_150_2B formed therebetween (FIG. 83). This step is performed by the likes of CVD, for example.

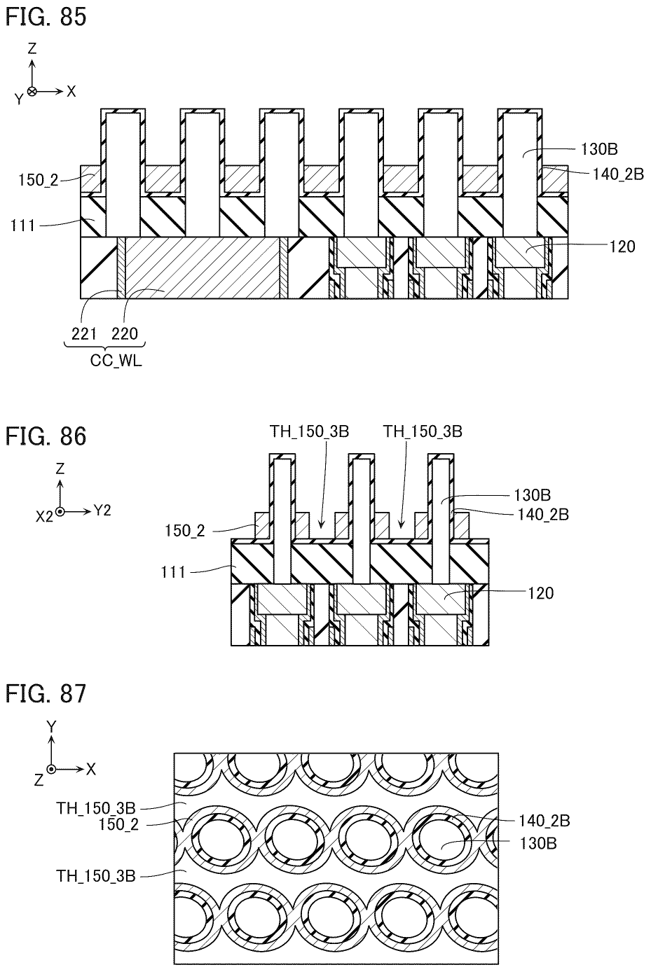

Next, as shown in FIGS. 85 to 87, for example, the conductive layer 150_2B is etched back to form the conductive layer 150_2. In this step, a portion below a portion where the opening TH_150_2B is formed, of the conductive layer 150_2B is removed, and in portions between the semiconductor layers 130B arranged in the Y2 direction, an opening TH_150_3B (FIG. 86) is formed. The opening TH_150_3B extends in the X-direction and the Z-direction, and penetrates the conductive layer 150_2B to expose a part of the insulating layer 140_2B formed on the upper surface of the insulating layer 111. This step results in the conductive layers 150_2 divided in the Y-direction (FIG. 87) being formed. This step is performed by the likes of RIE, for example.

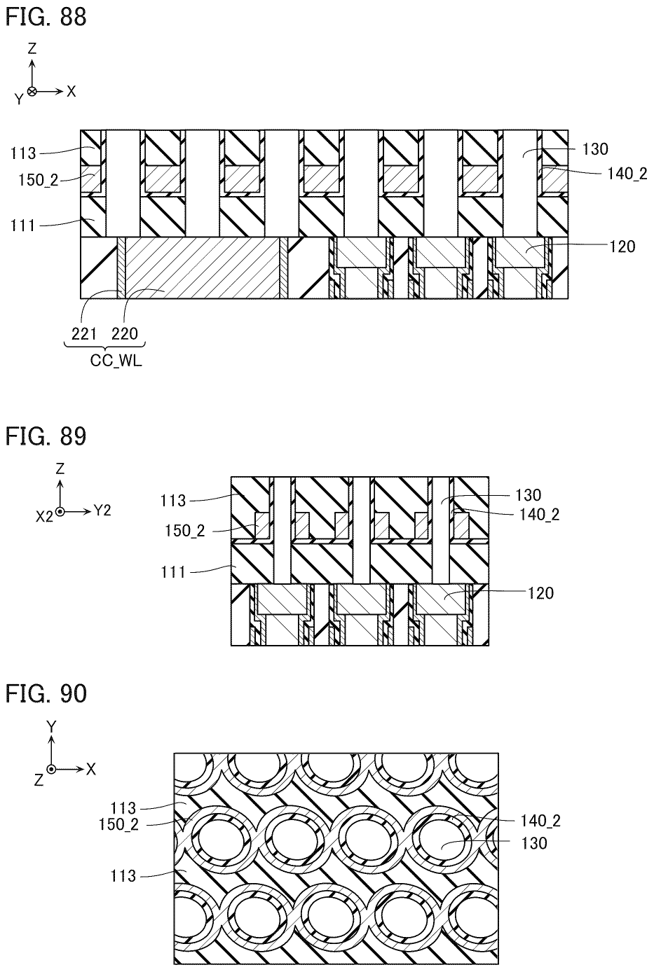

Next, as shown in FIGS. 88 to 90, for example, an insulating layer includes a similar material to the insulating layer 113 is formed on an upper surface of the structure shown in FIGS. 85 and 86, and an upper surface portion of the insulating layer and a part of the insulating layer 140_2B are removed, whereby the insulating layer 113, the semiconductor layer 130, and the insulating layer 140_2 are formed. This step is performed by the likes of CVD and CMP, for example.

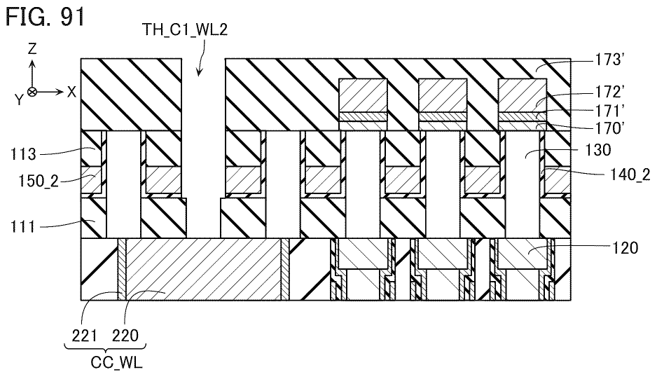

Next, as shown in FIG. 91, for example, the conductive layer 170′, the conductive layer 171′, and the conductive layer 172′, and the insulating layer 173′ are formed. This step is performed similarly to the step described with reference to FIGS. 41 to 46, for example.

Next, as shown in FIG. 91, for example, an opening TH_C1_WL2 is formed at a position corresponding to the electrode C1_WL2. The opening TH_C1_WL2 extends in the Z-direction and penetrates the insulating layers 173′, 113, the conductive layer 150_2, and the insulating layer 111 to expose the electrode C1_WLP. This step is performed by the likes of RIE, for example.

Next, the conductive layer 152_2 and the conductive layer 150a_2 (FIG. 63) are formed in the opening TH_C1_WL2, the plug LP and the bit line BL are formed similarly to in the step described with reference to FIGS. 49 to 52, and the wiring layer L_{UL} (FIG. 2), and so on, are formed, whereby the semiconductor device according to the second embodiment is manufactured.

### [Manufacturing Method 2 of Second Embodiment]

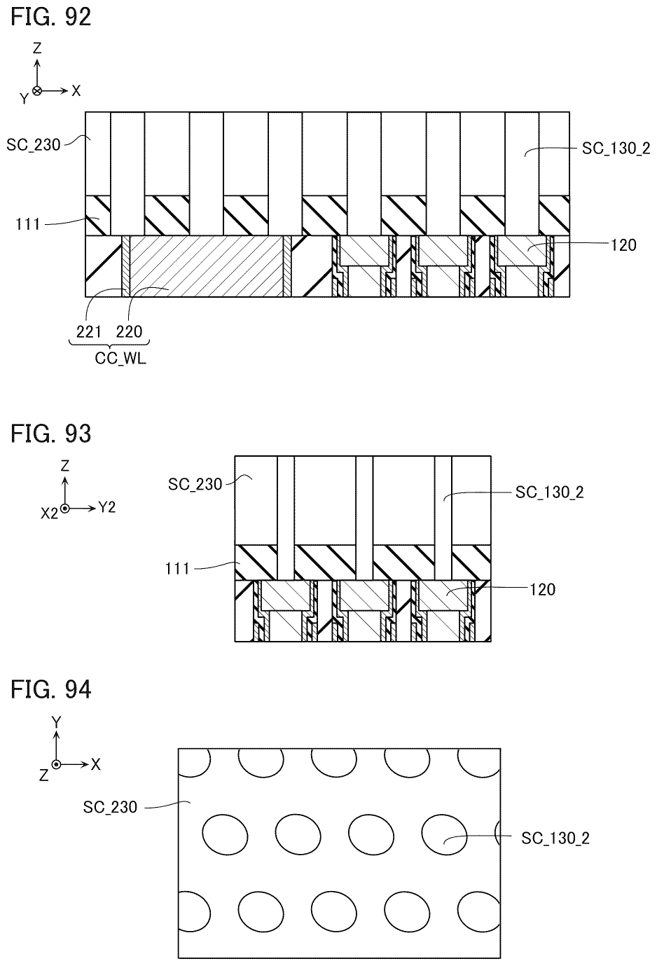

Next, a manufacturing method 2 of the semiconductor device according to the present embodiment will be described with reference to FIGS. 92 to 106. FIGS. 92 to 106 are schematic cross-sectional views and plan views for explaining the manufacturing method 2 of the semiconductor device according to the second embodiment.

Note that FIGS. 92, 95, 98, 101, and 104 are schematic cross-sectional views of portions corresponding to FIG. 63. FIGS. 93, 96, 99, 102, and 105 are schematic cross-sectional views corresponding to a portion in which the configuration shown in FIG. 5 has been cut along the line E-E′ and viewed along a direction of the arrows. FIGS. 94, 97, 100, 103, and 106 are plan views showing similar portions to in FIG. 5. Note that the drawings related to the manufacturing method are schematic, and that hereafter, for convenience of description, parts of configurations, and so on, thereof will sometimes be omitted.

In same manufacturing method, similar steps to the steps described with reference to FIGS. 67 to 72 are performed.

Next, as shown in FIGS. 92 to 94, for example, a sacrifice layer SC_130_2 of the likes of amorphous silicon (αSi) is formed inside the openings TH_130_2, TH_130_2a. This step is performed by the likes of CVD and CMP, for example.

Next, the sacrifice layer SC_230 is removed similarly to in the step described with reference to FIGS. 76 to 78, for example. This step results in the upper surface of the insulating layer 111 and an upper surface and a part of an outer peripheral surface of the sacrifice layer SC_130_2 being exposed.

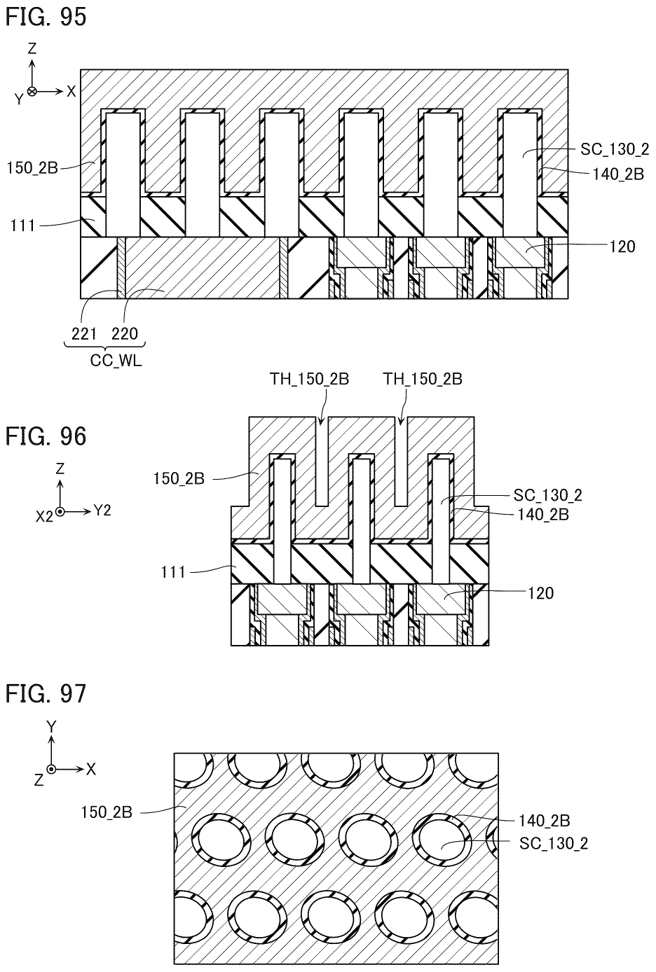

Next, as shown in FIGS. 95 to 97, for example, an insulating layer 140_2B including a similar material to the insulating layer 140_2 is formed on the upper surface and a part of the outer peripheral surface of the sacrifice layer SC_130_2, and on the upper surface of the insulating layer 111. This step is performed by the likes of CVD and ALD, for example.

Next, as shown in FIGS. 95 to 97, for example, the conductive layer 150_2B is formed. This step results in spaces between the sacrifice layers SC_130_2 arranged in the X-direction being filled by the conductive layer 150_2B (FIG. 95). On the other hand, spaces between the sacrifice layers SC_130_2 arranged in the Y2 direction are not filled by the conductive layer 150_2B, and the sacrifice layers SC_130_2 arranged in the Y2 direction have an opening TH_150_2B formed therebetween (FIG. 96). This step is performed by the likes of CVD, for example.

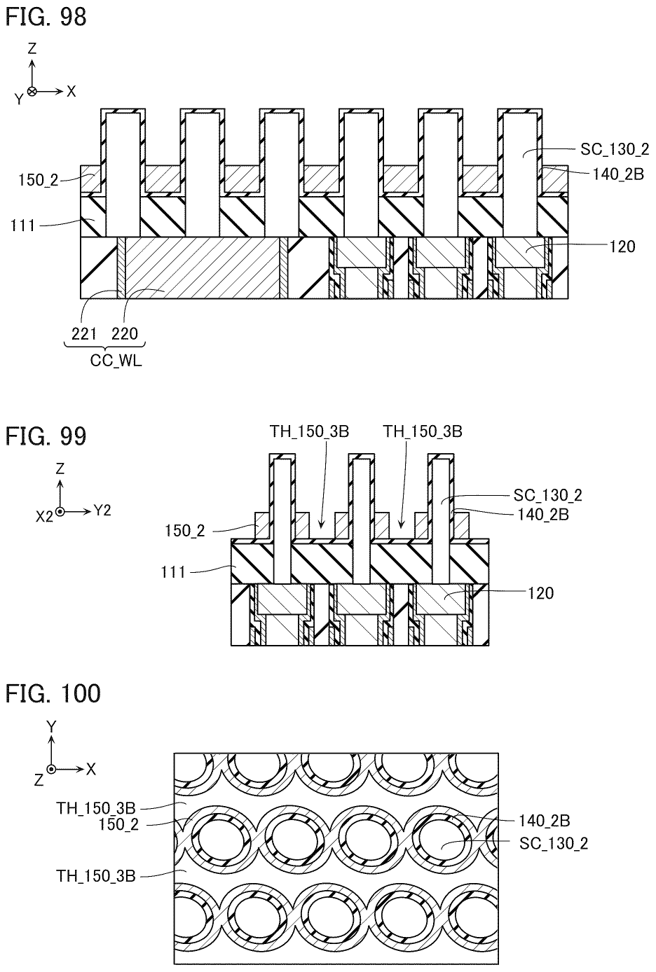

Next, as shown in FIGS. 98 to 100, for example, the conductive layer 150_2B is etched back to form the conductive layer 150_2. In this step, a portion below a portion where the opening TH_150_2B is formed, of the conductive layer 150_2B is removed, and in portions between the sacrifice layers SC_130_2 arranged in the Y2 direction, an opening TH_150_3B (FIG. 99) is formed. This step results in the conductive layers 150_2 divided in the Y-direction being formed. This step is performed by the likes of RIE, for example.

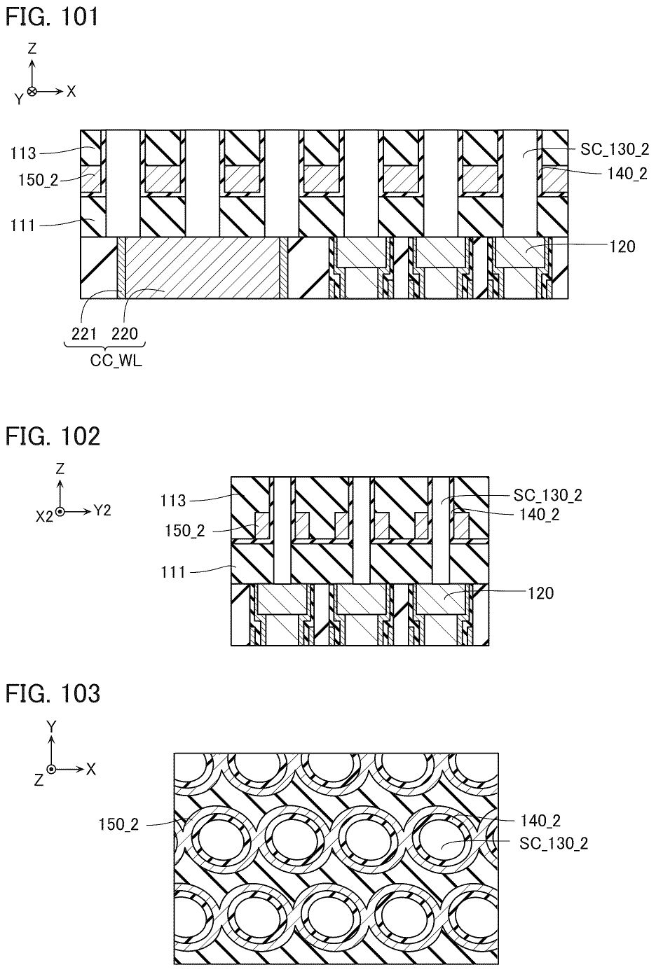

Next, as shown in FIGS. 101 to 103, for example, a similar material to the insulating layer 113 is formed on an upper surface of the structure shown in FIGS. 98 and 99, and an upper surface portion insulating layer and a part of the insulating layer 140_2B are removed, whereby the insulating layer 113 and the insulating layer 140_2 are formed, and the upper surface of the sacrifice layer SC_130_2 is exposed. This step is performed by the likes of CVD and CMP, for example.

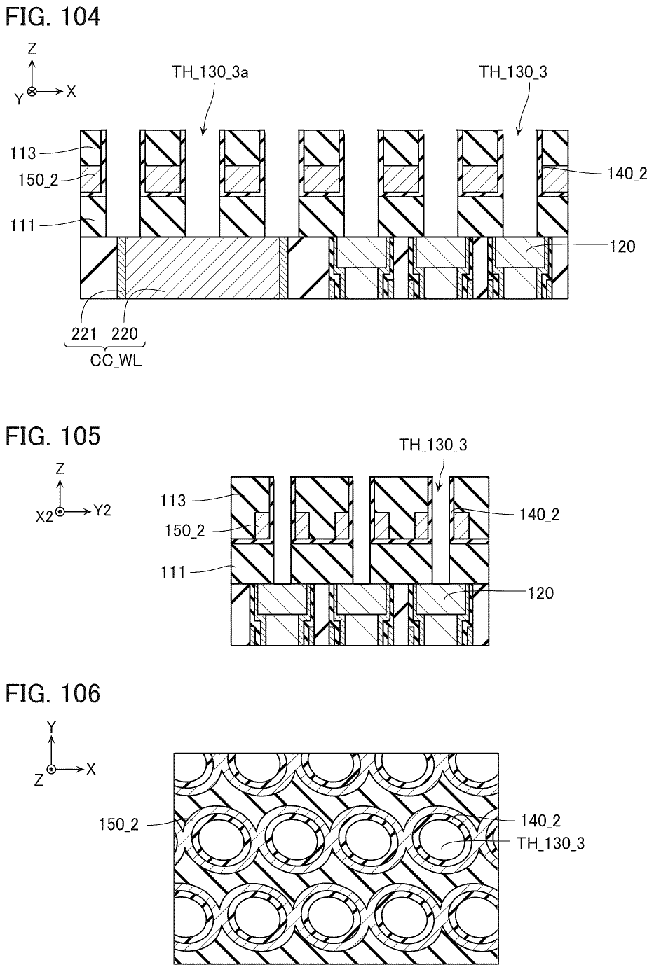

Next, as shown in FIGS. 104 to 106, for example, the sacrifice layer SC_130_2 is removed, and openings TH_130_3, TH_130_3a are formed. The openings TH_130_3, TH_130_3a extend in the Z-direction, expose on their side surfaces a part of the insulating layer 140_2, and the insulating layer 111, and expose on their bottom surfaces the likes of the conductive layer 120 and the through electrode CC_WL. This step is performed by the likes of wet etching, for example.

Next, the semiconductor layer 130 is formed inside the openings TH_130_3, TH_130_3a, and the semiconductor layer 130D1 is formed inside the opening TH_130_3a. This step is performed by the likes of CVD and CMP, for example.

Next, the steps described with reference to FIG. 91 onward are performed similarly to in the manufacturing method 1 of the second embodiment, and the semiconductor device according to the second embodiment is manufactured.

### [Advantages]

In the semiconductor device according to the present embodiment, too, similarly to in the first embodiment (FIG. 5), the width DT10 is greater than the width DX10.

In such a structure, in the manufacturing method 1, for example, in the step described with reference to FIGS. 82 to 84, the spaces between the semiconductor layers 130B arranged in the Y2 direction, that correspond to the positions where the semiconductor layers 130 are to be formed (FIGS. 82 to 84), will not be filled by the conductive layer 150_2B (FIG. 83). As a result, the conductive layers 150_2 formed by etching back the conductive layer 150_2B (FIGS. 85 to 87) will be connected in the X-direction, but divided in the Y-direction. In such a step, the conductive layer 150_2 can be formed in a self-arranging manner along the semiconductor layers 130B arranged in the X-direction.

Moreover, in the manufacturing method 2, for example, in the step described with reference to FIGS. 95 to 97, the spaces between the sacrifice layers SC_130_2 arranged in the Y2 direction, that correspond to the positions where the semiconductor layers 130 are to be formed (FIGS. 95 to 97), will not be filled by the conductive layer 150_2B (FIG. 96). As a result, the conductive layers 150_2 formed by etching back the conductive layer 150_2B (FIGS. 98 to 100) will be connected in the X-direction, but divided in the Y-direction. In such a step, the conductive layer 150_2 can be formed in a self-arranging manner along the sacrifice layers SC_130_2 arranged in the X-direction.

This enables manufacturing of a select transistor ST (FIG. 1) having excellent transistor characteristics, and a minute word line WL, that have high levels of integration. Moreover, costs during manufacturing can be reduced due to there being no need for a fine photolithography step for processing the conductive layer 150_2.

### [Modified Example of Second Embodiment]

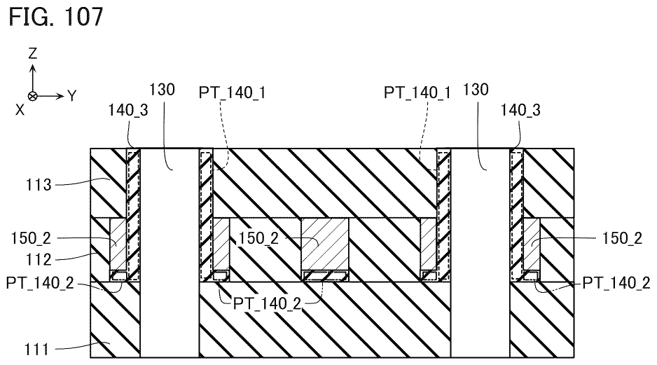

Next, a modified example of the semiconductor device according to the second embodiment will be described with reference to FIG. 107. FIG. 107 is a schematic cross-sectional view showing a configuration of a part of the semiconductor device according to the present modified example.

The semiconductor device according to the present modified example (FIG. 107) is provided with an insulating layer 140_3 instead of the insulating layer 140_2 (FIG. 65).

The insulating layer 140_3 (FIG. 107) is basically provided similarly to the insulating layer 140_2 (FIG. 65). However, the insulating layer 140_3 is not provided with a portion corresponding to the portion PT_140_3 of the insulating layer 140_2. The insulating layer 140_3 are divided in the Y-direction.

### Third Embodiment

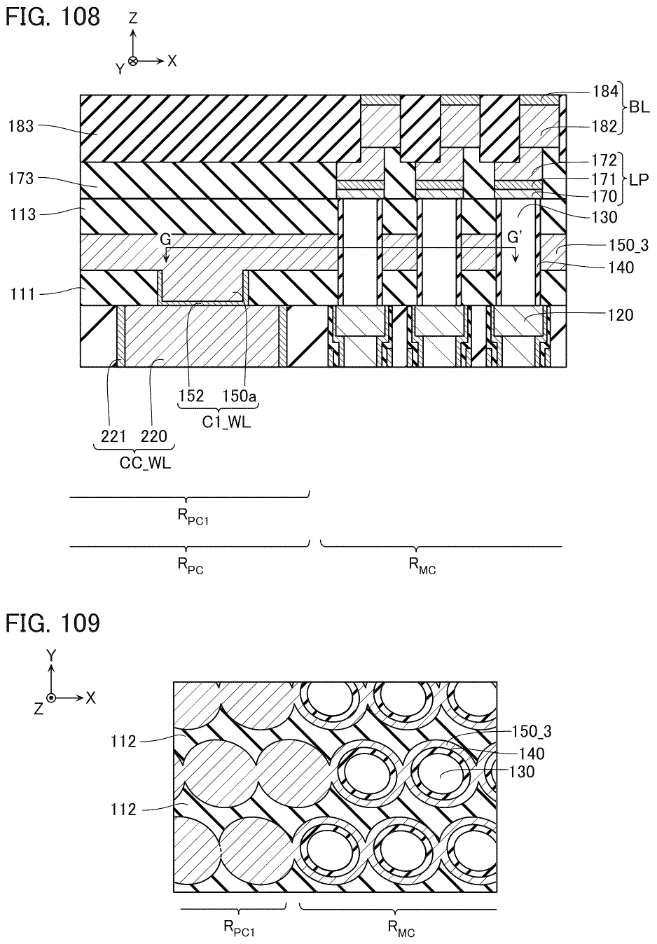

Next, a semiconductor device according to a third embodiment will be described using FIGS. 108 to 110. FIGS. 108 to 110 are respectively a schematic cross-sectional view, plan view, and perspective view showing a configuration of a part of the semiconductor device according to the third embodiment.

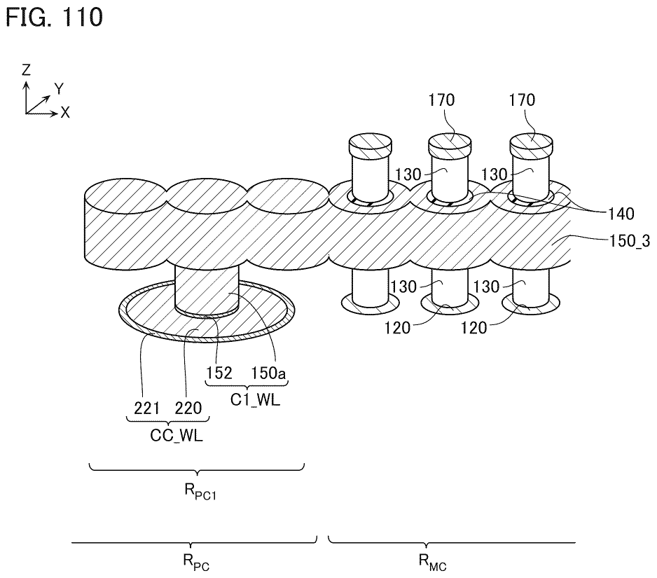

Note that FIG. 108 shows a portion corresponding to FIG. 11. FIG. 109 is a schematic plan view corresponding to a portion in which the configuration shown in FIG. 108 has been cut along the line G-G′ and viewed along a direction of the arrows. FIG. 110 shows a structure of the memory region R_{MC} and region R_{PC1}.

The semiconductor device according to the present embodiment is basically configured similarly to the semiconductor device according to the first embodiment (FIG. 11). However, the semiconductor device according to the present embodiment is provided with a conductive layer 150_3 (FIG. 108) instead of the conductive layer 150 (FIG. 11), and moreover, is not provided with the semiconductor layers 130D1, 130D2 in the region R_{PC1}.

The conductive layer 150_3 (FIG. 108) is basically provided similarly to the conductive layer 150 (FIG. 11). However, as shown in FIG. 110, for example, in the memory region R_{MC}, the conductive layer 150_3 is provided with substantially cylindrical portions ranging in the X-direction, that surround parts of the semiconductor layer 130 and the insulating layer 140, whereas in the region R_{PC1}, the conductive layer 150_3 is provided with substantially circular column-like portions ranging in the X-direction.

### [Manufacturing Method of Third Embodiment]

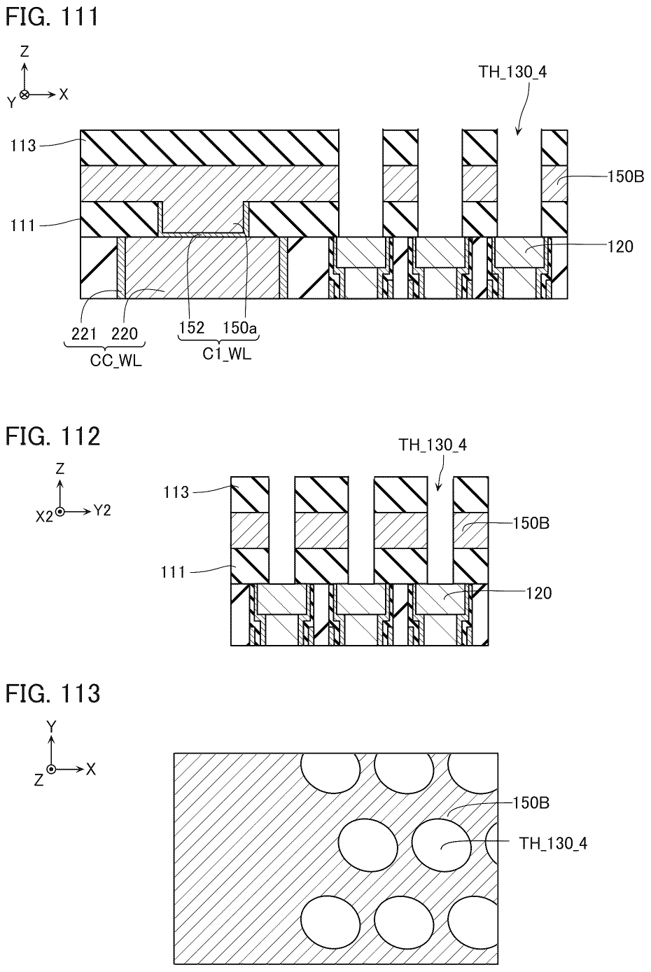

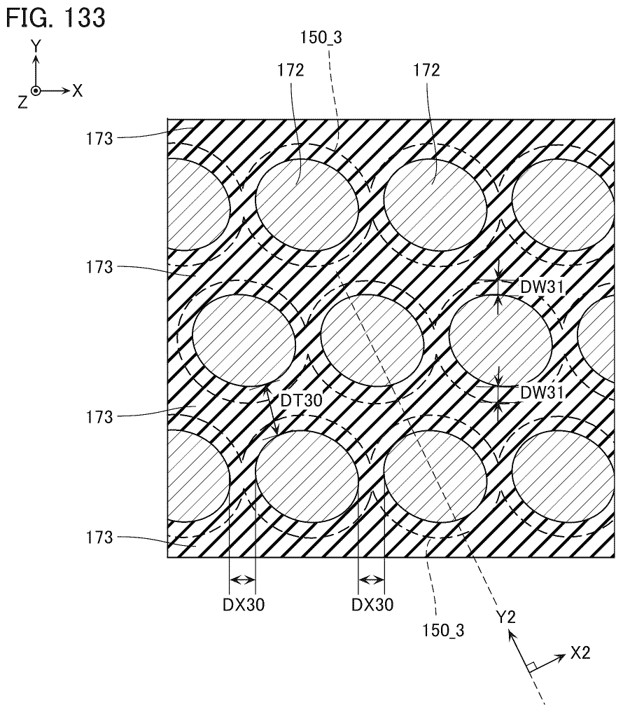

Next, a manufacturing method of the semiconductor device according to the present embodiment will be described with reference to FIGS. 111 to 132. FIGS. 111 to 132 are schematic cross-sectional views and plan views for explaining the manufacturing method of the semiconductor device according to the third embodiment.

Note that FIGS. 111, 114, 117, 119, 121, 123, 125, 127, and 130 are schematic cross-sectional views of portions corresponding to FIG. 108. FIGS. 112, 115, 118, 120, 122, 124, 126, 128, and 131 are schematic cross-sectional views corresponding to a portion in which the configuration shown in FIG. 5 has been cut along the line E-E′ and viewed along a direction of the arrows. FIGS. 113, 116, 129, and 132 are schematic plan views of portions corresponding to FIG. 109. Note that the drawings related to the manufacturing method are schematic, and that hereafter, for convenience of description, parts of configurations, and so on, thereof will sometimes be omitted.

In same manufacturing method, similar steps to in the manufacturing method of the first embodiment are performed up to the step described with reference to FIGS. 14 and 15.

Next, as shown in FIGS. 111 and 112, for example, a conductive layer including a similar material to the conductive layer 150_3, and the conductive layer 150a, are formed on the upper surface of the structure shown in FIGS. 14 and 15 and inside the opening TH_150 (FIG. 14), and the insulating layer 113 is formed on an upper surface of the conductive layer. This step is performed by the likes of CVD, for example.

Next, as shown in FIGS. 111 to 113, for example, an opening TH_130_4 is formed. The opening TH_130_4 extends in the Z-direction and penetrates the insulating layer 113, the conductive layer including a similar material to the conductive layer 150_3, and the insulating layer 111 to expose the conductive layer 120. This step results in a conductive layer 150B being formed. This step may be performed using a mask material HM10, similarly to the step described with reference to FIGS. 19 to 21, for example.

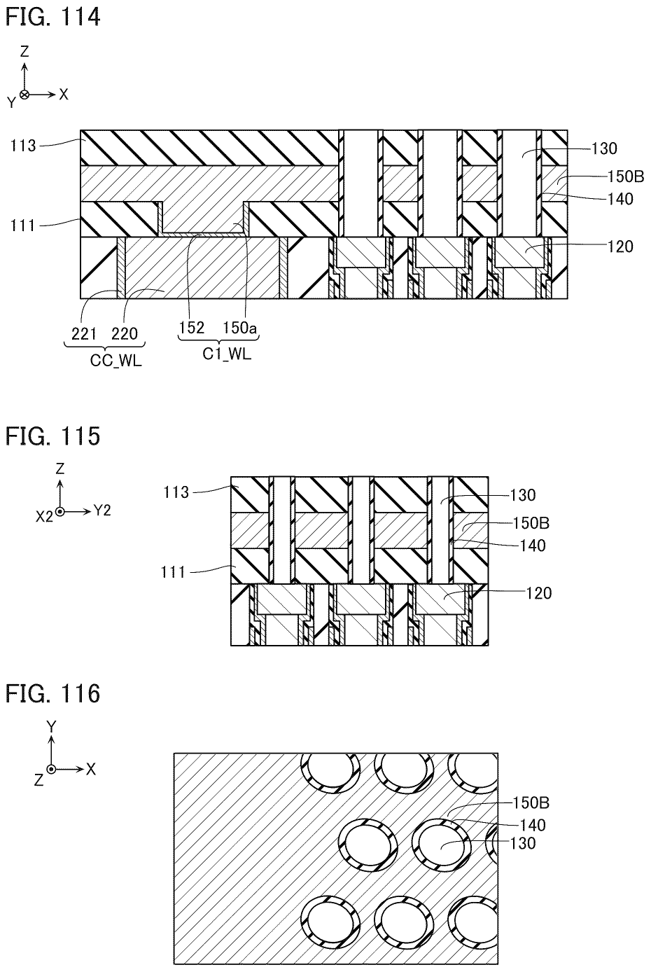

Next, as shown in FIGS. 114 to 116, for example, the insulating layer 140 and the semiconductor layer 130 are formed inside the opening TH_130_4. In this step, the insulating layer 140 is formed by an insulating layer including a similar material to the insulating layer 140 being formed on an inner side surface and a bottom surface of the opening TH_130_4, after which a portion formed on the bottom surface of the opening TH_130_4, of the insulating layer is removed. The semiconductor layer 130 is formed so as to contact an inner side surface of the insulating layer 140 and fill in the opening TH_130_4. This step is performed by the likes of ALD, CVD, RIE, and CMP, for example.

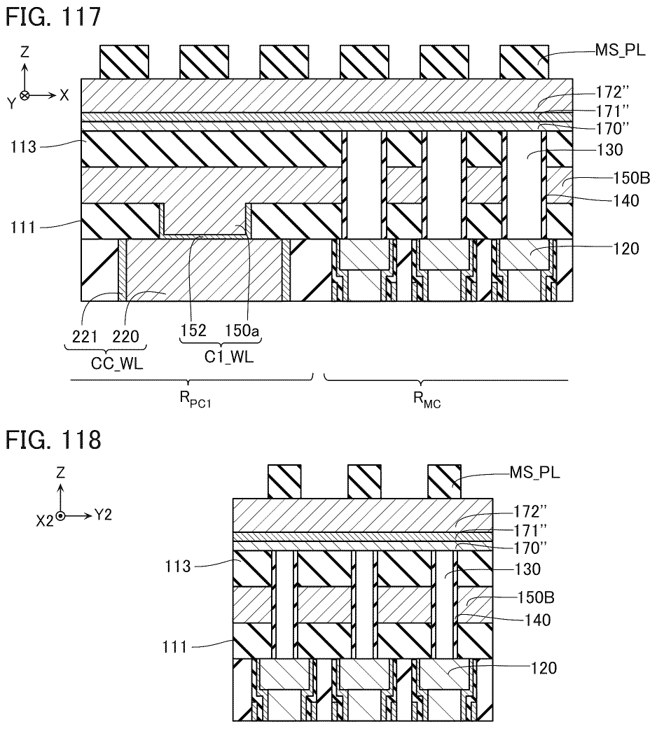

Next, as shown in FIGS. 117 and 118, for example, a conductive layer 170″, a conductive layer 171″, and a conductive layer 172″ are formed in order on an upper surface of the structure shown in FIGS. 114 and 115. Moreover, a mask material MS_PL of the likes of silicon oxide (SiO₂) or silicon nitride (SiN) is formed by photolithography, and so on, at a position corresponding to the conductive layer 170, the conductive layer 171, and the conductive layer 172 in the memory region R_{MC}, and moreover, with a similar shape, arrangement, and so on, to in the memory region R_{MC}, for example, in the region R_{PC1}. This step is performed by the likes of CVD and RIE, for example.

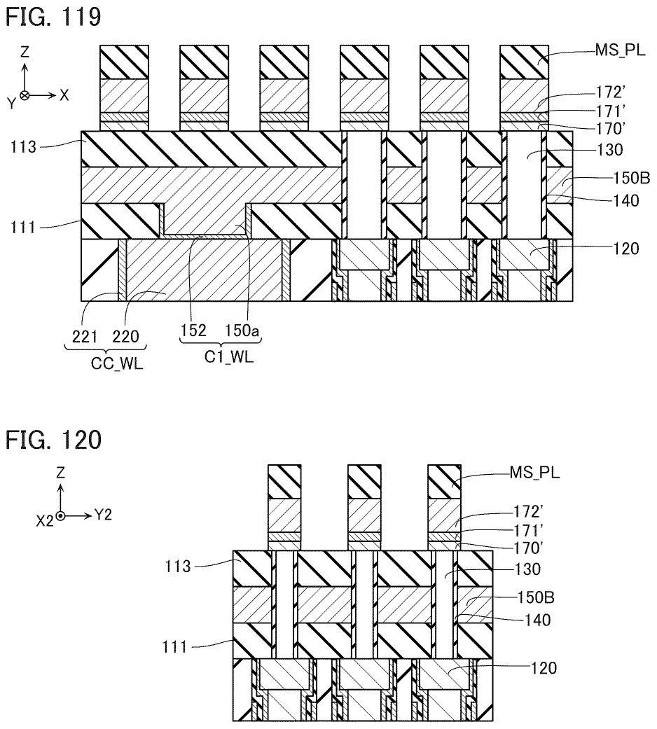

Next, as shown in FIGS. 119 and 120, for example, portions of the conductive layer 170″, the conductive layer 171″, and the conductive layer 172″ that are not covered by the mask material MS_PL are removed to form a conductive layer 170′, conductive layer 171′, and the conductive layer 172′. This step is performed by the likes of RIE, for example.

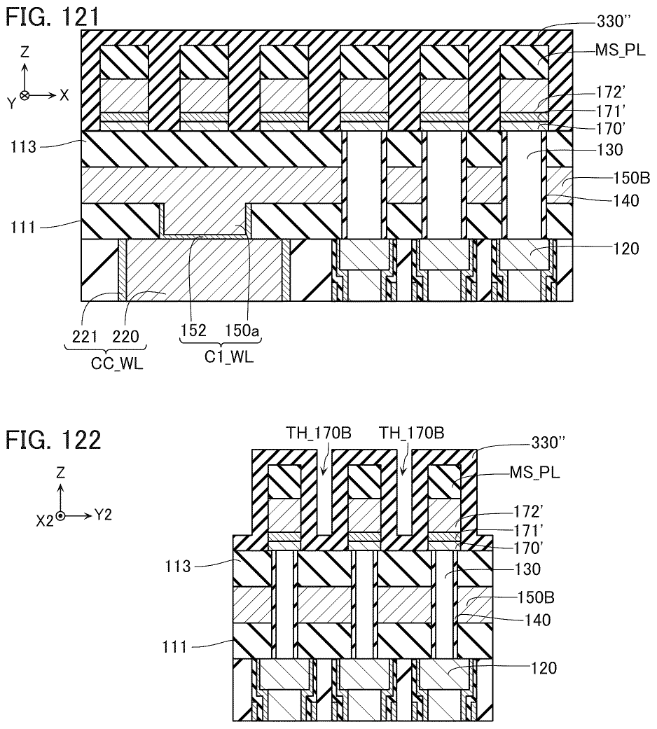

Next, as shown in FIGS. 121 and 122, for example, an insulating layer 330″ of the likes of silicon oxide (SiO₂) is formed on an upper surface of the structure shown in FIGS. 119 and 120. This step results in spaces between structures including the conductive layer 170′, the conductive layer 171′, and the conductive layer 172′ that are arranged in the X-direction, being filled by the insulating layer 330″ (FIG. 121). On the other hand, spaces between structures including the conductive layer 170′, the conductive layer 171′, and the conductive layer 172′ that are arranged in the Y2 direction are not filled by the insulating layer 330″, and an opening TH_170B is formed (FIG. 122). This step is performed by the likes of CVD and ALD, for example.

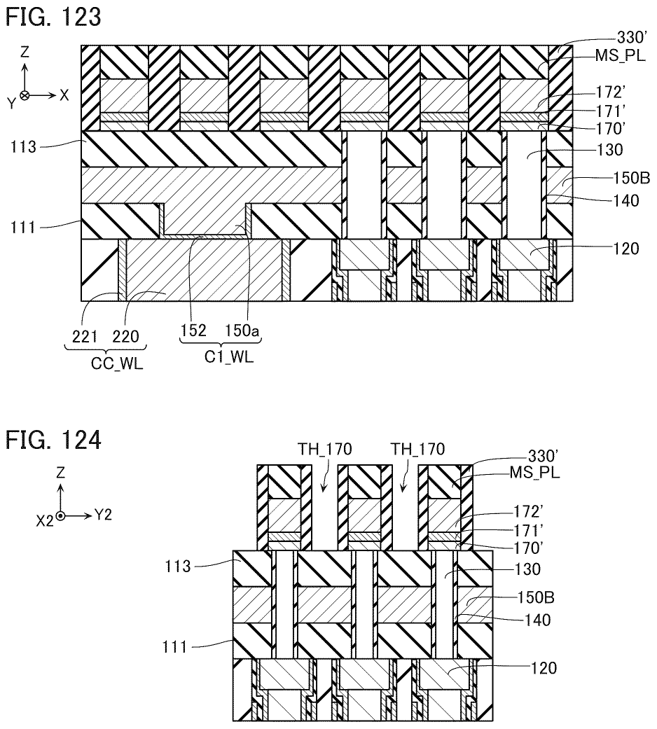

Next, as shown in FIGS. 123 and 124, for example, the insulating layer 330″ is etched back to form an insulating layer 330′. In this step, a portion of the insulating layer 330″ contacting a bottom surface of the opening TH_170B is removed, and an opening TH_170 (FIG. 124) is formed. The opening TH_170 extends in the X-direction and the Z-direction, and exposes at its bottom surface a part of the insulating layer 113. This step is performed by the likes of RIE, for example.

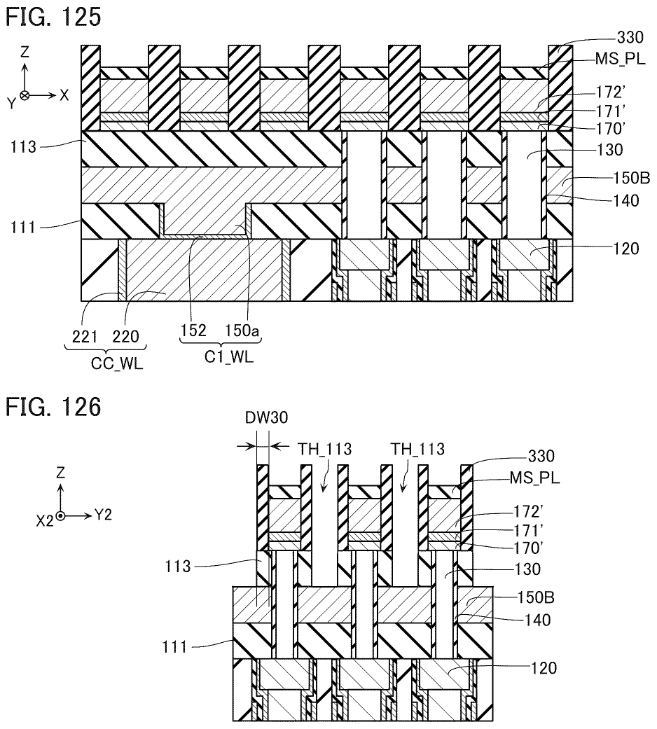

Next, as shown in FIGS. 125 and 126, for example, a portion where an upper surface is exposed of the insulating layer 113 is removed to form an opening TH_113. The opening TH_113 extends in the X-direction and the Z-direction, and exposes at its bottom surface a part of an upper surface of the conductive layer 150B. This step results in an insulating layer 330 being formed. An outer peripheral surface in the Y2 direction of the insulating layer 330 is provided a distance DW30 to an outer side from an outer peripheral surface in the Y2 direction of the conductive layer 172′, for example. Moreover, in this step, a part of an upper surface of the mask material MS_PL is also removed. This step is performed by the likes of RIE, for example.

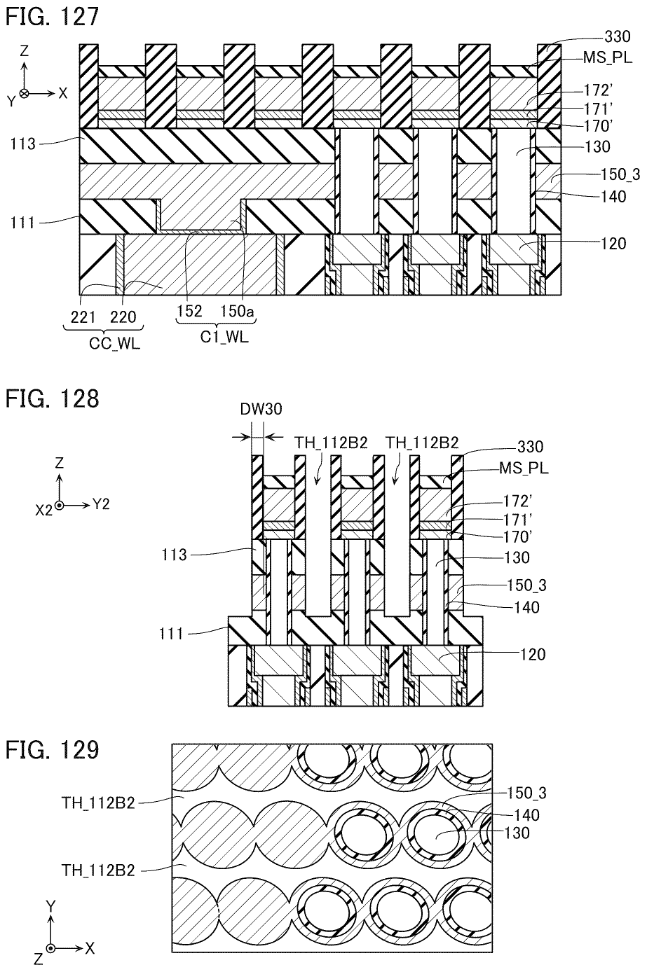

Next, as shown in FIGS. 127 to 129, for example, a portion where an upper surface is exposed of the conductive layer 150B is removed to form an opening TH_112B2. The opening TH_112B2 extends in the X-direction and the Z-direction, and penetrates the conductive layer 150B to expose at its bottom surface a part of an upper surface of the insulating layer 111. This step results in the conductive layer 150_3 being formed. Note that when an outer peripheral surface of the opening TH_112B2 is processed to be perpendicular to the substrate, an outer peripheral surface in the Y2 direction of the conductive layer 150_3 will be provided the distance DW30 to an outer side from the outer peripheral surface in the Y2 direction of the conductive layer 172′, for example. This step is performed by the likes of RIE, for example.

Note that when due to processing conditions, the outer peripheral surface of the opening TH_112B2 is not in a perpendicular direction from the substrate, but has become inclined, viewed in the Z-direction, the outer peripheral surface in the Y2 direction of the conductive layer 150_3 may be provided a smaller width than the distance DW30 to an outer side from the outer peripheral surface in the Y2 direction of the conductive layer 172′, or may be provided a larger width than the distance DW30 to an outer side from the outer peripheral surface in the Y2 direction of the conductive layer 172′, for example. Moreover, the outer peripheral surface in the Y2 direction of the conductive layer 150_3 may coincide with the outer peripheral surface in the Y2 direction of the conductive layer 172′, or the outer peripheral surface in the Y2 direction of the conductive layer 150_3 may be located a certain distance to an inner side of the outer peripheral surface in the Y2 direction of the conductive layer 172′.

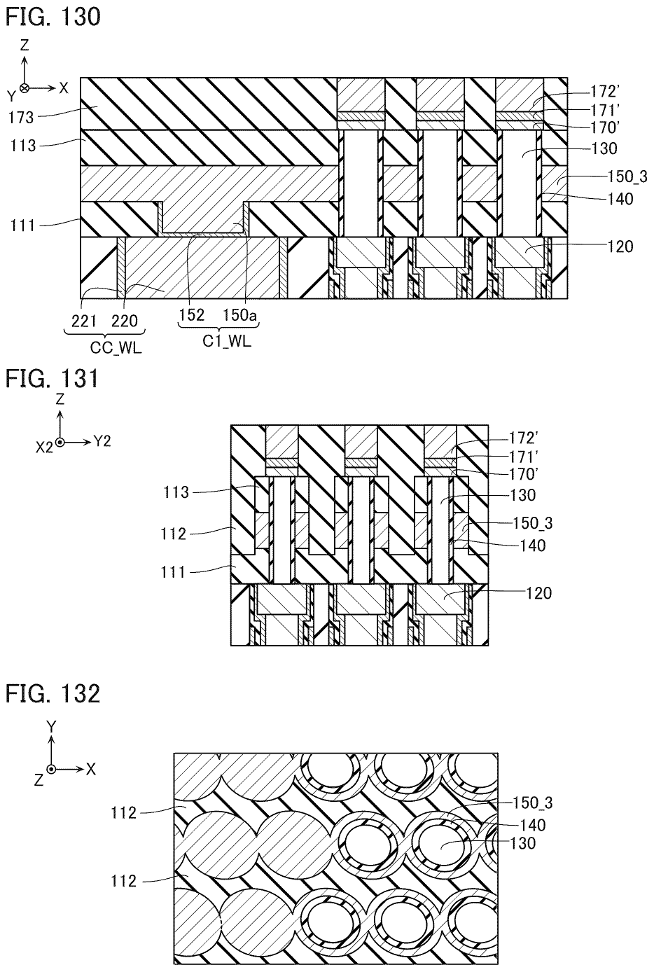

Next, as shown in FIGS. 130 to 132, for example, the insulating layer 330 and the mask material MS_PL are removed, and the insulating layer 112 is formed in the opening TH_112B2. Moreover, in the region R_{PC1}, the conductive layer 170′, conductive layer 171′, and the conductive layer 172′ not connected to the semiconductor layer 130 are removed, after which the insulating layer 173 is formed between the structures including the conductive layer 170′, the conductive layer 171′, and the conductive layer 172′. This step is performed by the likes of RIE, for example.

Next, for example, the steps described with reference to FIG. 47 onward are performed similarly to in the manufacturing method of the first embodiment, and the semiconductor device according to the third embodiment is manufactured.

### [Positional Relationship Between Conductive Layer 172 and Conductive Layer 150_3]

FIG. 133 is a schematic plan view showing a configuration of a part of the semiconductor device according to the third embodiment. Note that FIG. 133 shows a portion corresponding to FIG. 6. Moreover, in FIG. 133, in order to show positional relationships, the conductive layers 150_3 not appearing in same cross section are shown by broken lines.

As shown in FIG. 133, for example, in an XY cross section including the plurality of conductive layers 172, a closest distance between an outer peripheral surface of one of two conductive layers 172 arranged in the X-direction and an outer peripheral surface of the other of the two conductive layers 172 arranged in the X-direction, is a distance DX30. Moreover, a closest distance between an outer peripheral surface of one of two conductive layers 172 arranged in the Y2 direction and an outer peripheral surface of the other of the two conductive layers 172 arranged in the Y2 direction, is a distance DT30. The distance DT30 is greater than the distance DX30.

Moreover, in the example shown in FIG. 133, for example, viewed in the Z-direction, a part of a surface on one side in the Y-direction of the conductive layer 150_3 is provided a distance DW31 to an outer side from a part of a surface on one side in the Y-direction of the conductive layer 172.

Note that the distance DW31 may be about the same as the distance DW30 (FIG. 128), or may be greater than or less than the distance DW30.

Moreover, in addition to the example shown in FIG. 133, viewed in the Z-direction, a part of a surface on one side in the Y-direction of the conductive layer 150_3 may be provided a certain width to an inner side of a part of a surface on one side in the Y-direction of the conductive layer 172, or may coincide with a part of a surface on one side in the Y-direction of the conductive layer 172.

### [Advantages]

In the semiconductor device according to the present embodiment, as shown in FIG. 133, the distance DT30 which is the closest distance between fellow outer peripheral surfaces of two conductive layers 172 arranged in the Y2 direction is greater than the distance DX30 which is the closest distance between fellow outer peripheral surfaces of two conductive layers 172 arranged in the X-direction.

In such a structure, in the step described with reference to FIGS. 121 and 122, the spaces between the conductive layers 172′ arranged in the Y2 direction will not be filled by the insulating layer 330″ (FIG. 122). As a result, the conductive layers 150_3 formed by etching back the insulating layer 330″ (FIGS. 127 to 129) will be connected in the X-direction, but divided in the Y-direction. In such a step, the conductive layer 150_3 can be formed in a self-arranging manner along the conductive layers 172′ arranged in the X-direction.

This enables manufacturing of a select transistor ST (FIG. 1) having excellent transistor characteristics, and a minute word line WL, that have high levels of integration. Moreover, costs during manufacturing can be reduced due to there being no need for a fine photolithography step for processing the conductive layer 150_3.

### Other Embodiments

That concludes description of the semiconductor devices according to the first through third embodiments. However, the semiconductor devices according to these embodiments are merely exemplifications, and specific configuration, operation, and so on, can be appropriately adjusted.

For the semiconductor devices according to the first through third embodiments, as shown in FIG. 5, for example, there have been shown examples where in the XY cross section, a shape of the semiconductor layer 130 is an ellipse. Moreover, FIG. 5 has shown an example where a major axis direction of the ellipse does not coincide with the X-direction and the Y-direction. However, the shape of these semiconductor layers 130 is merely an exemplification, and a specific shape, and so on, can be appropriately adjusted.

The shape of the semiconductor layer 130 may be a true circle or a racetrack shape, in addition to an ellipse, for example. Moreover, in the case where the shape of the semiconductor layer 130 is an ellipse or racetrack shape, a major axis direction of the ellipse or racetrack shape may coincide with, or may differ from the X-direction, the Y-direction, the X2 direction, and the Y2 direction.

In the above description, for example, there has been described an example where the capacitor Cap (FIG. 1) is connected to the select transistor ST (FIG. 1). In such an example, shape, structure, and so on, of the capacitor Cap are appropriately adjustable.

Moreover, in the above description, there has been described an example where the capacitor Cap (FIG. 1) is adopted as the memory portion connected to the select transistor ST (FIG. 1). However, the memory portion need not be the capacitor Cap. For example, the memory portion may include a ferroelectric material, a ferromagnetic material, a chalcogen material of the likes of GeSbTe, or another material, and may utilize characteristics of these materials to store data. For example, any of these materials may be included in the insulating layer between the electrodes forming the capacitor Cap, in any of the structures described above.

Moreover, in the above description, there has been shown an example where the semiconductor layer 130 functioning as the channel region of the select transistor ST (FIG. 1) extends in the Z-direction and has a substantially circular column-like shape, for example. However, the semiconductor layer 130 may have a substantially cylindrical shape extending in the Z-direction. Moreover, an insulating layer including the likes of silicon oxide (SiO₂) and having a substantially circular column-like shape extending in the Z-direction, may be provided inside the semiconductor layer 130.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a substrate;
a first oxide semiconductor layer and a second oxide semiconductor layer which extend in a first direction intersecting a surface of the substrate, are arranged in a second direction intersecting the first direction, and include a first metal element and oxygen (O);
a first conductive layer which extends in the second direction and faces a part of an outer peripheral surface of the first oxide semiconductor layer and a part of an outer peripheral surface of the second oxide semiconductor layer;
a first gate insulating layer provided between the first oxide semiconductor layer and the first conductive layer; and
a second gate insulating layer provided between the second oxide semiconductor layer and the first conductive layer, wherein
in a first cross section which extends in the second direction and a third direction intersecting the first direction and the second direction, and includes the first oxide semiconductor layer, the second oxide semiconductor layer, and the first conductive layer, the first conductive layer includes:
a ring-like first portion which is provided separated by a first width from the outer peripheral surface of the first oxide semiconductor layer, and surrounds the first oxide semiconductor layer; and
a ring-like second portion which is provided separated by the first width from the outer peripheral surface of the second oxide semiconductor layer, and surrounds the second oxide semiconductor layer, and
a part of a circle, ellipse, or racetrack shape circumscribing the first portion, and a part of a circle, ellipse, or racetrack shape circumscribing the second portion overlap.

2. The semiconductor device according to claim 1, further comprising:
a third oxide semiconductor layer which extends in the first direction, is arranged with respect to the first oxide semiconductor layer in a direction intersecting the first direction but differing from the second direction, and includes the first metal element and oxygen (O);
a second conductive layer which is arranged adjacently in the third direction with the first conductive layer, extends in the second direction, and faces a part of an outer peripheral surface of the third oxide semiconductor layer; and
a third gate insulating layer provided between the third oxide semiconductor layer and the second conductive layer, wherein
the first cross section further includes the third oxide semiconductor layer and the second conductive layer, and
in the first cross section:
a closest distance between the outer peripheral surface of the first oxide semiconductor layer and the outer peripheral surface of the second oxide semiconductor layer is a second width; and
a closest distance between the outer peripheral surface of the first oxide semiconductor layer and the outer peripheral surface of the third oxide semiconductor layer is a third width,
the third width is greater than the second width.

3. The semiconductor device according to claim 1, further comprising:
a fourth oxide semiconductor layer which extends in the first direction, is arranged in the second direction with the first oxide semiconductor layer, has a part of an outer peripheral surface facing the first conductive layer, and includes the first metal element and oxygen (O);
a through electrode which is provided on one side in the first direction with respect to the fourth oxide semiconductor layer, and extends in the first direction; and
a third conductive layer which is provided between the first conductive layer and the through electrode, and surrounds another part of the outer peripheral surface of the fourth oxide semiconductor layer, wherein
the first conductive layer and the through electrode are electrically connected via the third conductive layer.

4. The semiconductor device according to claim 1, further comprising:
a first insulating layer which extends in the first direction, is arranged in the second direction with the first oxide semiconductor layer, and has a part of an outer peripheral surface facing the first conductive layer;
a through electrode which is provided on one side in the first direction with respect to the first insulating layer, and extends in the first direction; and
a third conductive layer which is provided between the first conductive layer and the through electrode, and surrounds another part of the outer peripheral surface of the first insulating layer, wherein
the first conductive layer and the through electrode are electrically connected via the third conductive layer.

5. The semiconductor device according to claim 1, further comprising
a fifth oxide semiconductor layer which extends in the first direction, is arranged in the second direction with the first oxide semiconductor layer, has a part of an outer peripheral surface facing the first conductive layer, and includes the first metal element and oxygen (O), wherein
in a second cross section which extends in the second direction and the third direction, and includes the fifth oxide semiconductor layer and the first conductive layer,
the first conductive layer includes a ring-like third portion which is provided separated by the first width from the outer peripheral surface of the fifth oxide semiconductor layer, and surrounds the fifth oxide semiconductor layer, and
a part of the third portion is an end portion in the second direction of the first conductive layer.

6. The semiconductor device according to claim 1, further comprising
a second insulating layer which extends in the first direction, is arranged in the second direction with the first oxide semiconductor layer, and has a part of an outer peripheral surface facing the first conductive layer, wherein
in a third cross section which extends in the second direction and the third direction, and includes the second insulating layer and the first conductive layer,
the first conductive layer includes a ring-like fourth portion which surrounds the outer peripheral surface of the second insulating layer, and
a part of the fourth portion is an end portion in the second direction of the first conductive layer.

7. The semiconductor device according to claim 1, further comprising
a third insulating layer which is provided on a surface on one side in the first direction of the first conductive layer, wherein
the third insulating layer includes the same material as the first gate insulating layer and the second gate insulating layer, and is continuous with the first gate insulating layer and the second gate insulating layer.

8. The semiconductor device according to claim 2, further comprising:
a third insulating layer provided on a surface on one side in the first direction of the first conductive layer; and
a fourth insulating layer provided on a surface on one side in the first direction of the second conductive layer, wherein
the third insulating layer includes the same material as the first gate insulating layer, and is continuous with the first gate insulating layer,
the fourth insulating layer includes the same material as the third gate insulating layer, and is continuous with the third gate insulating layer, and
a fifth insulating layer which includes the same material as the third insulating layer and the fourth insulating layer, and is continuous with the third insulating layer and the fourth insulating layer is provided between the third insulating layer and the fourth insulating layer.

9. The semiconductor device according to claim 1, wherein
the first metal element is one element selected from the group consisting of indium (In), gallium (Ga), aluminum (Al), zinc (Zn), tin (Sn), titanium (Ti), tungsten (W), and molybdenum (Mo).

10. The semiconductor device according to claim 1, further comprising
a capacitor layer which is provided on one side in the first direction with respect to the first oxide semiconductor layer and the second oxide semiconductor layer, wherein
the capacitor layer comprises capacitor structures each electrically connected to the first oxide semiconductor layer and the second oxide semiconductor layer.

11. A semiconductor device comprising:
a substrate;
a first oxide semiconductor layer and a second oxide semiconductor layer which extend in a first direction intersecting a surface of the substrate, are arranged in a second direction intersecting the first direction, and include a first metal element and oxygen (O);
a first conductive layer which extends in the second direction and faces a part of an outer peripheral surface of the first oxide semiconductor layer and a part of an outer peripheral surface of the second oxide semiconductor layer;
gate insulating layers each provided between the first oxide semiconductor layer and the first conductive layer, and between the second oxide semiconductor layer and the first conductive layer; and
a first electrode and a second electrode each connected to one ends in the first direction of the first oxide semiconductor layer and the second oxide semiconductor layer, wherein
when viewed in the first direction, a part of a surface on one side in a third direction intersecting the first direction and the second direction, of the first conductive layer is:
provided coinciding with a surface on one side in the third direction of the first electrode and the second electrode; or
provided a first distance to an outer side or an inner side from the surface on one side in the third direction of the first electrode and the second electrode.

12. The semiconductor device according to claim 11, wherein
the first electrode includes a fourth conductive layer which contacts one end in the first direction of the first oxide semiconductor layer, and includes a second metal element and oxygen (O), and
the second metal element is one element selected from the group consisting of indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo).

13. The semiconductor device according to claim 11, further comprising:
a third oxide semiconductor layer which extends in the first direction, is arranged with respect to the first oxide semiconductor layer in a direction intersecting the first direction and differing from the second direction, and includes the first metal element and oxygen (O);
a third electrode connected to one end in the first direction of the third oxide semiconductor layer; and
a second conductive layer which is arranged adjacently in the third direction with the first conductive layer, extends in the second direction, and faces a part of an outer peripheral surface of the third oxide semiconductor layer, wherein
in a cross section which extends in the second direction and the third direction, and includes the first electrode, the second electrode, and the third electrode:
a closest distance between an outer peripheral surface of the first electrode and an outer peripheral surface of the second electrode is a second distance; and
a closest distance between the outer peripheral surface of the first electrode and an outer peripheral surface of the third electrode is a third distance,
the third distance is greater than the second distance.

14. The semiconductor device according to claim 11, wherein
the first metal element is one element selected from the group consisting of indium (In), gallium (Ga), aluminum (Al), zinc (Zn), tin (Sn), titanium (Ti), tungsten (W), and molybdenum (Mo).

15. The semiconductor device according to claim 11, further comprising
a capacitor layer which is provided on one side in the first direction with respect to the first oxide semiconductor layer and the second oxide semiconductor layer, wherein
the capacitor layer comprises capacitor structures each electrically connected to the first oxide semiconductor layer and the second oxide semiconductor layer.
